(19) United States
(12) Patent Application Publication
(10) Pub. No.: US 2026/0047256 A1
(43) Pub. Date: Feb. 12, 2026

(54) DISPLAY DEVICE AND ELECTRONIC DEVICE INCLUDING THE SAME

(71) Applicant: Samsung Display Co., LTD., Yongin-si (KR)

(72) Inventors: JUCHAN PARK, Yongin-si (KR); YOOMIN KO, Yongin-si (KR); SUNHO KIM, Yongin-si (KR); Hyewon Kim, Yongin-si (KR); Yerim Son, Yongin-si (KR); PILSUK LEE, Yongin-si (KR); CHUNG SOCK CHOI, Yongin-si (KR); SUNGJIN HONG, Yongin-si (KR)

(73) Assignee: Samsung Display Co., LTD., Yongin-si (KR)

(21) Appl. No.: 19/255,352

(22) Filed: Jun. 30, 2025

(30) Foreign Application Priority Data
Aug. 12, 2024 (KR) 10-2024-0107285

(51) Int. Cl. H10H 29/49; H10H 29/37; H10H 29/80

(52) U.S. Cl. CPC H10H 29/49; H10H 29/37; H10H 29/8321

(57) ABSTRACT

A display device includes a substrate including a display area and a peripheral area, a power supply line disposed in the peripheral area and supplying a low power voltage, multiple first electrodes disposed in the display area and supplied with a high power voltage, a pixel defining layer disposed on the first electrodes and exposing a portion of each of the first electrodes to define an emission area, an auxiliary connection electrode disposed on the pixel defining layer and connected to the power supply line, an electrode layer disposed on the first electrodes and the auxiliary connection electrode, connected to the auxiliary connection electrode, and supplied with the low power voltage, and a separator disposed on the auxiliary connection electrode, overlapping a portion of the auxiliary connection electrode, and separating the electrode layer into multiple second electrodes spaced apart from each other in the display area.

### CROSS-REFERENCE TO RELATED APPLICATION(S)

This application claims priority under 35 U.S.C. § 119 to and benefits from Korean Patent Application No. 10-2024-0107285 filed on Aug. 12, 2024 in the Korean Intellectual Property Office, the entire contents of which are incorporated herein by reference.

### BACKGROUND

### 1. Technical Field

Embodiments of the disclosure relate to a display device that provides visual information and an electronic device including the display device.

### 2. Description of the Related Art

As information technology develops, the importance of a display device, which is a connection medium between a user and information, has been emphasized. The display device includes light emitting elements and pixel driving circuits for driving the light emitting elements. The light emitting elements are driven by the pixel driving circuits to emit light. In order to improve a reliability of the display device, studies on connections between the light emitting elements and the pixel driving circuits are being conducted.

### SUMMARY

Embodiments of the disclosure provide a display device with improved display quality.

Embodiments of the disclosure also provide an electronic device including the display device.

Additional features of the inventive concepts will be set forth in the description which follows, and in part will be apparent from the description, or may be learned by practice of the inventive concepts.

A display device according to an embodiment may include a substrate including a display area and a peripheral area disposed around the display area, a power supply line disposed in the peripheral area and supplying a low power voltage, a plurality of first electrodes disposed in the display area and supplied with a high power voltage, a pixel defining layer disposed on the plurality of first electrodes and exposing a portion of each of the plurality of first electrodes to define an emission area, an auxiliary connection electrode disposed on the pixel defining layer and electrically connected to the power supply line, an electrode layer disposed on the plurality of first electrodes and the auxiliary connection electrode, electrically connected to the auxiliary connection electrode, and supplied with the low power voltage, and a separator disposed on the auxiliary connection electrode, overlapping a portion of the auxiliary connection electrode, and separating the electrode layer into a plurality of second electrodes spaced apart from each other in the display area.

In an embodiment, the display device may further include an auxiliary electrode disposed in the display area and electrically connected to the power supply line, and an auxiliary connection pattern disposed between the auxiliary electrode and the auxiliary connection electrode. The auxiliary connection pattern may include an auxiliary electrode connection portion connected to the auxiliary electrode and a light emitting connection portion connected to the auxiliary connection electrode.

In an embodiment, in a plan view, the light emitting connection portion may be disposed between the emission area and the separator.

In an embodiment, in a plan view, the light emitting connection portion may overlap the separator.

In an embodiment, the pixel defining layer may define first, second, and third emission areas emitting light of different colors. The plurality of second electrodes separated from each other by the separator may respectively overlap the first, second, and third emission areas.

In an embodiment, in a plan view, the separator may have a mesh structure surrounding each of the plurality of second electrodes.

In an embodiment, in a plan view, the auxiliary connection electrode may have a mesh structure surrounding each of the first, second, and third emission areas.

In an embodiment, in a plan view, a profile of the auxiliary connection electrode may correspond to a profile of the separator.

In an embodiment, a width of the auxiliary connection electrode may be greater than a width of the separator.

In an embodiment, the separator may overlap a central portion in a width direction of the auxiliary connection electrode and may expose opposing side portions in the width direction of the auxiliary connection electrode. In the display area, the plurality of second electrodes may contact the opposing side portions of the auxiliary connection electrode exposed by the separator.

In an embodiment, the display device may further include a voltage transmission electrode disposed on the power supply line. The voltage transmission electrode may include a power line connection portion connected to the power supply line and an auxiliary connection electrode connection portion connected to the auxiliary connection electrode.

In an embodiment, the voltage transmission electrode and the plurality of second electrodes may be disposed in a same layer. In a boundary between the display area and the peripheral area, the separator may separate the electrode layer into the plurality of second electrodes disposed in the display area and the voltage transmission electrode disposed in the peripheral area.

In an embodiment, an edge portion of the separator may be disposed at a boundary between the display area and the peripheral area. An edge portion of the auxiliary connection electrode may be disposed at the boundary between the display area and the peripheral area, and may include a first side portion disposed in the display area in a width direction, a second side portion disposed in the peripheral area in the width direction, and a central portion disposed between the first side portion and the second side portion. The separator may overlap the central portion of the auxiliary connection electrode and an edge portion of the separator may expose each of the first side portion and the second side portion of the auxiliary connection electrode. In the peripheral area, the auxiliary connection electrode connection portion of the voltage transmission electrode may contact the second side portion of the auxiliary connection electrode exposed by the edge portion of the separator.

In an embodiment, in the display area, the plurality of second electrodes may contact the first side portion of the auxiliary connection electrode exposed by the edge portion of the separator.

In an embodiment, the auxiliary connection electrode may include first, second, and third auxiliary connection electrodes respectively surrounding the first, second, and third emission areas in a plan view.

In an embodiment, in a plan view, the first, second, and third auxiliary connection electrodes may be spaced apart from each other.

In an embodiment, in a plan view, each of the first, second, and third auxiliary connection electrodes may have a closed ring shape.

In an embodiment, the first auxiliary connection electrode may include a first side portion that is far from the first emission area in a width direction and a second side portion that is close to the first emission area in the width direction. The separator may overlap the first side portion of the first auxiliary connection electrode and may expose the second side portion of the first auxiliary connection electrode. In the display area, one of the plurality of second electrodes overlapping the first emission area may contact the second side portion of the first auxiliary connection electrode exposed by the separator.

A display device according to an embodiment may include a substrate including a display area and a peripheral area disposed around the display area, a power supply line disposed in the peripheral area and supplying a low power voltage, an auxiliary electrode disposed in the display area and electrically connected to the power supply line, an auxiliary connection pattern disposed on the auxiliary electrode, electrically connected to the auxiliary electrode, and including a first conductive layer and a second conductive layer sequentially stacked on each other, a plurality of first electrodes disposed in the display area and supplied with a high power voltage, a pixel defining layer disposed on the auxiliary connection pattern and the plurality of first electrodes and exposing a portion of each of the plurality of first electrodes to define an emission area, an electrode layer disposed on the auxiliary connection pattern and the plurality of first electrodes, electrically connected to the auxiliary connection pattern, and supplied with the low power voltage, and a separator disposed on the pixel defining layer and separating the electrode layer into a plurality of second electrodes spaced apart from each other in the display area. The auxiliary connection pattern may have a tip portion defined by a portion of the second conductive layer protruding from the first conductive layer;

An electronic device according to an embodiment may include a window, a housing coupled with the window to provide an internal space, and a display device accommodated in the internal space provided between the housing and the window. The display device may include a substrate including a display area and a peripheral area disposed around the display area, a power supply line disposed in the peripheral area and supplying a low power voltage, a plurality of first electrodes disposed in the display area and supplied with a high power voltage, a pixel defining layer disposed on the plurality of first electrodes and exposing a portion of each of the plurality of first electrodes to define an emission area, an auxiliary connection electrode disposed on the pixel defining layer and electrically connected to the power supply line, an electrode layer disposed on the plurality of first electrodes and the auxiliary connection electrode, electrically connected to the auxiliary connection electrode, and supplied with the low power voltage, and a separator disposed on the auxiliary connection electrode, overlapping a portion of the auxiliary connection electrode, and separating the electrode layer into a plurality of second electrodes spaced apart from each other in the display area.

According to embodiments of the disclosure, a leakage current (lateral leakage) between adjacent light emitting elements may be reduced. A voltage drop (IR drop) phenomenon of a low power voltage provided to a cathode included in the light emitting elements may be reduced. Accordingly, a display quality of the display device may be improved.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the disclosure, and together with the description serve to explain the invention.

FIG. 1A is a schematic plan view illustrating a display device according to an embodiment.

FIG. 1B is a schematic plan view illustrating a display device according to an embodiment.

FIG. 2 is a schematic diagram of an equivalent circuit illustrating a circuit structure of a pixel included in the display device of FIGS. 1A and 1B according to an embodiment.

FIG. 3 is a schematic plan view illustrating a portion of the display device of FIGS. 1A and 1B according to an embodiment.

FIG. 4 is an enlarged schematic view illustrating one of unit emission areas of FIG. 3 according to an embodiment.

FIG. 5 is a schematic cross-sectional view taken along line I-I′ of FIG. 4 according to an embodiment.

FIGS. 6 and 7 are schematic plan views illustrating a portion of a display device according to an embodiment.

FIG. 8 is an enlarged schematic view illustrating one of unit emission areas of FIG. 7 according to an embodiment.

FIG. 9 is a schematic cross-sectional view taken along line II-II′ of FIG. 8 according to an embodiment.

FIGS. 10 and 11 are schematic plan views illustrating a portion of a display device according to an embodiment.

FIG. 12 is an enlarged schematic view illustrating one of unit emission areas of FIG. 11 according to an embodiment.

FIG. 13 is a schematic cross-sectional view taken along line III-III′ of FIG. 12 according to an embodiment.

FIGS. 14 and 15 are schematic plan views illustrating a portion of a display device according to an embodiment.

FIG. 16 is an enlarged schematic view illustrating one of unit emission areas of FIG. 15 according to an embodiment.

FIG. 17 is a schematic cross-sectional view taken along line IV-IV′ of FIG. 16 according to an embodiment.

FIG. 18 is a schematic plan view illustrating a display device according to an embodiment.

FIG. 19 is a schematic cross-sectional view taken along line V-V′ of FIG. 18 according to an embodiment.

FIG. 20 is a schematic block diagram illustrating an electronic device according to an embodiment.

FIG. 21 is a schematic view illustrating an example in which the electronic device of

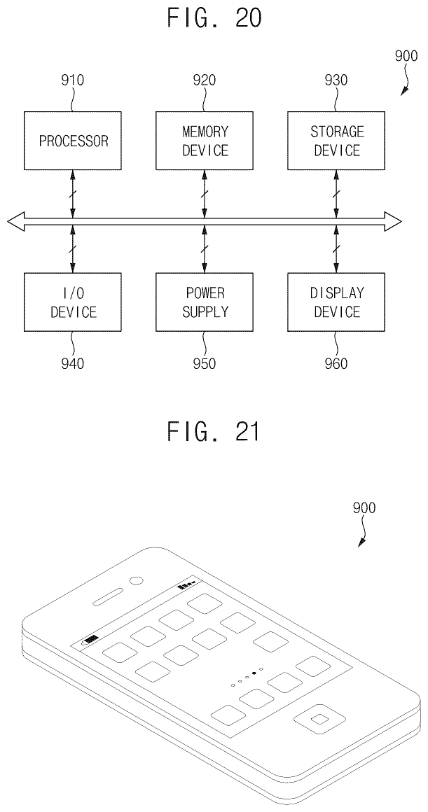

FIG. 20 is implemented as a smartphone.

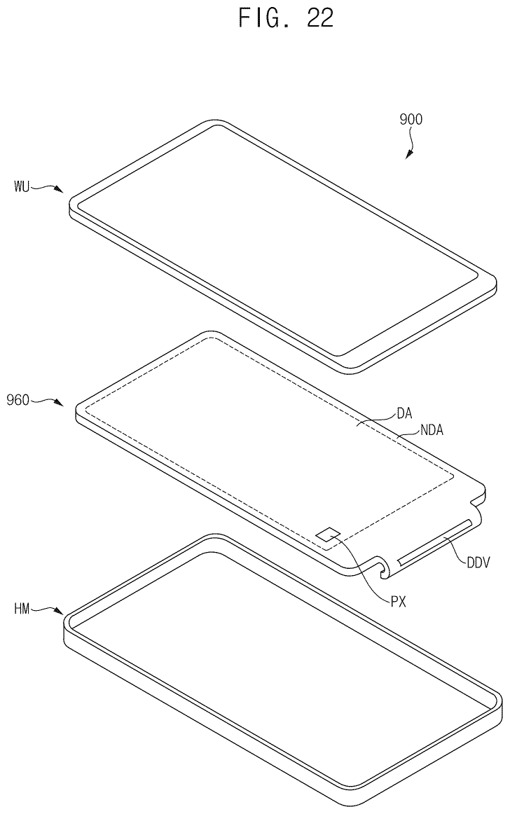

FIG. 22 is an exploded schematic plan view of the electronic device of FIG. 21.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or redisposed without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the disclosure. Further, the blocks, parts, and/or modules of some embodiments may be physically combined into more complex blocks, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

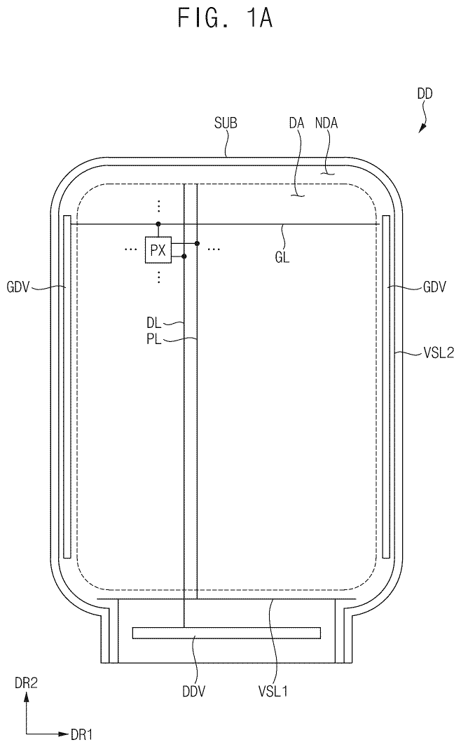

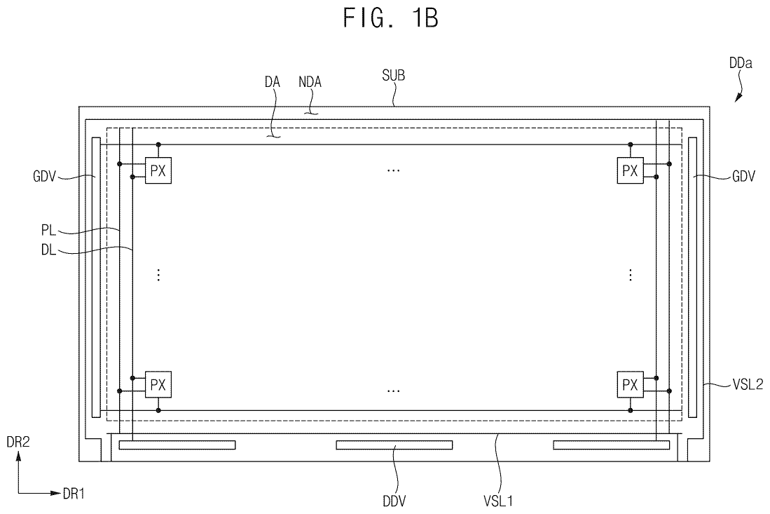

FIG. 1A is a schematic plan view illustrating a display device according to an embodiment. FIG. 1B is a schematic plan view illustrating a display device according to an embodiment.

In this specification, a plane may be defined by a first direction DR1 and a second direction DR2 intersecting the first direction DR1. For example, the first direction DR1 and the second direction DR2 may be perpendicular to each other. Each of a display device and various components or layers may have a thickness extending in a third direction intersecting the plane. In other words, the third direction may be perpendicular to each of the first direction DR1 and the second direction DR2.

Referring to FIGS. 1A and 1B, a display device DD (or DDa) may be a device activated according to an electrical signal. For example, the display device DD may be a small-sized display device used in a small-sized electronic device, such as a smart phone, a mobile phone, a smart watch, a game console, a camera, or the like. For example, the display device DDa may be a medium and large-sized display device used in medium and large-sized electronic devices, such as a notebook computer, a tablet PC, a television, a computer monitor, a vehicle monitor, an external billboard, or the like. FIG. 1A illustrates the display device DD as an embodiment of the small-sized display device, and FIG. 1B illustrates the display device DDa as an embodiment of the medium and large-sized display device.

The display device DD (or DDa) may include a display area DA and a peripheral area NDA. The display area DA may be an area that displays an image by generating light or controlling a transmittance of light provided from an external light source. The peripheral area NDA may be located around the display area DA. For example, the peripheral area NDA may surround at least a portion of the display area DA in a plan view. In an embodiment, the peripheral area NDA may be an area that does not display an image. However, the disclosure is not limited thereto, and an image may be displayed in at least a portion of the peripheral area NDA. For example, a light emitting element that emits light may be disposed in at least a portion of the peripheral area NDA.

The display device DD (or DDa) may include a substrate SUB, pixels PX, gate lines GL, data lines DL, a data driver DDV, a gate driver GDV, power lines PL, a first power supply line VSL1, and a second power supply line VSL2.

The substrate SUB may serve as a base of the display device DD (or DDa). In an embodiment, examples of the material that can be used as the substrate SUB may include glass, quartz, silicon, polymers, or the like. These may be used alone or in combination with each other. The substrate SUB may have a single-layer structure or a multi-layer structure in which multiple layers including different materials are stacked on each other.

The pixels PX may be disposed in the display area DA on the substrate SUB. The pixels PX may be electrically connected to the gate lines GL, the data lines DL, and the power lines PL. For example, the pixels PX may be disposed in a matrix form in the first direction DR1 and the second direction DR2. Each of the pixels PX may include a pixel driving circuit and a light emitting element. The light emitting element may emit light. The light emitting element may be an organic light emitting diode or an inorganic light emitting diode.

Each of the gate lines GL and each of the data lines DL may cross each other. For example, each of the gate lines GL may generally extend in the first direction DR1, and the gate lines GL may be disposed in the second direction DR2. Each of the data lines DL may generally extend in the second direction DR2, and the data lines DL may be disposed in the first direction DR1. Each of the power lines PL may generally extend in the second direction DR2, and the power lines PL may be disposed in the first direction DR1. However, the disclosure is not limited thereto.

The data driver DDV may be disposed in the peripheral area NDA on the substrate SUB. The data driver DDV may generate data voltages. The data driver DDV may output the data voltages to the data lines DL. The data voltages may be applied to the pixels PX through the data lines DL.

In an embodiment, the data driver DDV may be mounted on the substrate SUB. However, the disclosure is not limited thereto, and the data driver DDV may be disposed on a flexible film coupled to the substrate SUB in a chip on film (“COF”) manner.

In an embodiment, the display device DDa of FIG. 1B may include multiple data drivers DDV. For example, the data drivers DDV may be disposed on a side portion of the display area DA in the second direction DR2. For example, the data drivers DDV may be disposed on a long side of the display device DDa. However, the disclosure is not limited thereto, and the data drivers DDV may be disposed on both side portions of the display area DA in the second direction DR2.

The gate driver GDV may be disposed in the peripheral area NDA on the substrate SUB. The gate driver GDV may generate gate signals. The gate driver GDV may output the gate signals to the gate lines GL. The gate signals may be applied to the pixels PX through the gate lines GL. In an embodiment, gate drivers GDV may be disposed on both side portions of the display area DA in the first direction DR1. However, the disclosure is not limited thereto.

The number or arrangement of the data drivers DDV and the number or arrangement of the gate drivers GDVs illustrated in FIGS. 1A and 1B are merely examples, and the disclosure is not limited thereto.

In an embodiment, an emission driver generating emission control signals may be further disposed in the peripheral area NDA. The emission control signals may be applied to the pixels PX through emission control lines.

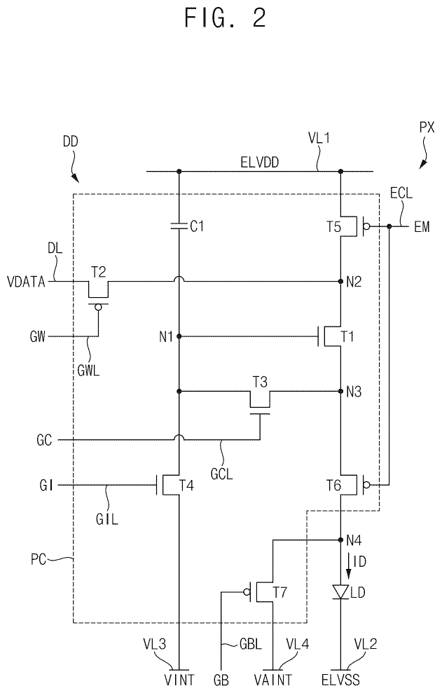

The first power supply line VSL1 may be disposed in the peripheral area NDA. The first power supply line VSL1 may supply a first power voltage ELVDD (see FIG. 2) having a high voltage level to the pixels PX. The first power voltage may be provided to the pixel driving circuit through the power lines PL. The first power voltage may be referred to as a high power voltage.

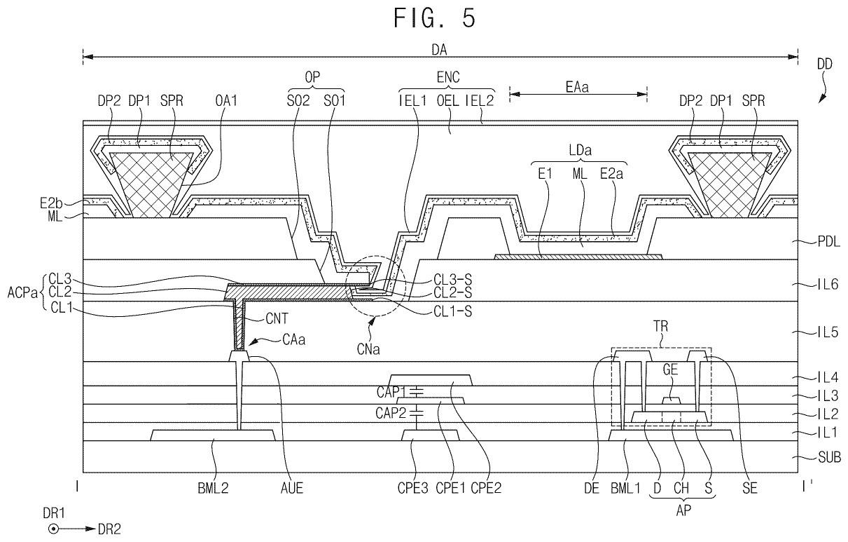

The second power supply line VSL2 may be disposed in the peripheral area NDA. The second power supply line VSL2 may supply a second power voltage ELVSS (see FIG. 2) having a low voltage level to the pixels PX. The second power voltage may be provided to a cathode (e.g., a second electrode E2a of FIG. 5) of the light emitting element. The second power voltage may be referred to as a low power voltage.

FIGS. 1A and 1B illustrate that the first power supply line VSL1 extends to correspond to a side of the display area DA and the second power supply line VSL2 extends to correspond to the remaining three sides of the display area DA. However, the disclosure is not limited thereto, and the shape or arrangement of the first power supply line VSL1 and the second power supply line VSL2 may be variously changed according to embodiments of the disclosure.

Although FIG. 1A illustrates that the display device DD has a substantially rectangular planar shape having short sides each extending in the first direction DR1 and long sides each extending in the second direction DR2 in a plan view, the disclosure is not limited thereto. Although FIG. 1B illustrates that the display device DDa has a substantially rectangular planar shape having long sides each extending in the first direction DR1 and short sides each extending in the second direction DR2 in a plan view, the disclosure is not limited thereto. For example, the planar shape of each of the display devices DD and DDa may be variously changed according to embodiments of the disclosure.

Descriptions below with the drawings may be substantially equally applied to the display device DD of FIG. 1A and the display device DDa of FIG. 1B. Therefore, for the convenience of description, the display devices DD and DDa are both referred to as the display device DD below.

FIG. 2 is a schematic diagram of an equivalent circuit illustrating a circuit structure of a pixel included in the display device of FIGS. 1A and 1B according to an embodiment.

Referring to FIG. 2, the pixel PX may include a light emitting element LD and a pixel driving circuit PC connected to the light emitting element LD. In an embodiment, the pixel driving circuit PC may include first to seventh transistors T1, T2, T3, T4, T5, T6, and T7 and a first capacitor C1. However, the disclosure is not limited thereto, and some of the components of the pixel driving circuit PC may be omitted, or other components may be added. In other words, the circuit structure (e.g., the number or arrangement of the transistors, the number or arrangement of the capacitor) of the pixel PX illustrated in FIG. 2 is merely example, and may be variously changed according to embodiments of the disclosure.

FIG. 2 illustrates that the first transistor T1, the third transistor T3, and the fourth transistor T4 are n-type transistors, and the second transistor T2, the fifth transistor T5, the sixth transistor T6, and the seventh transistor T7 are p-type transistors. However, the disclosure is not limited thereto, and some of the first to seventh transistors T1, T2, T3, T4, T5, T6, and T7 may be n-type transistors, and others may be p-type transistors. For example, the first transistor T1 may be an n-type transistor, and the second to seventh transistors T2, T3, T4, T5, T6, and T7 may be p-type transistors.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and both of the active pattern of the n-type transistor and the active pattern of the p-type transistor may include a silicon semiconductor material.

The pixel driver circuit PC may be connected to first to fourth gate lines GWL, GCL, GIL, and GBL, a data line DL, first to fourth voltage lines VL1, VL2, VL3, and VL4, and an emission control line ECL. The first gate line GWL may transmit a first gate signal GW. The second gate line GCL may transmit a second gate signal GC. The third gate line GIL may transmit a third gate signal GI. The fourth gate line GBL may transmit a fourth gate signal GB. The data line DL may transmit a data voltage VDATA. The first voltage line VL1 may transmit a first power voltage ELVDD having a high voltage level. The first voltage line VL1 may be the power line PL of FIG. 1. The second voltage line VL2 may transmit a second power voltage ELVSS having a low voltage level. The third voltage line VL3 may transmit a gate initialization voltage VINT. The fourth voltage line VL4 may transmit an anode initialization voltage VAINT.

The first transistor T1 may include a gate terminal, a first terminal, and a second terminal. In an embodiment, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The first transistor T1 may provide a driving current ID to the light emitting element LD.

The second transistor T2 may include a gate terminal, a first terminal, and a second terminal. In an embodiment, the first terminal of the second transistor T2 may be a source, and the second terminal of the second transistor T2 may be a drain. The gate terminal of the second transistor T2 may receive the first gate signal GW through the first gate line GWL. The first terminal of the second transistor T2 may receive the data voltage VDATA through the data line DL. The second terminal of the second transistor T2 may be connected to the second node N2.

The second transistor T2 may be turned on or off in response to the first gate signal GW. For example, in case that the second transistor T2 is the p-type transistor, the second transistor T2 may be turned off in case that the first gate signal GW has a positive voltage level, and the second transistor T2 may be turned on in case that the first gate signal GW has a negative voltage level. In case that the second transistor T2 is the n-type transistor, the second transistor T2 may be turned off in case that the first gate signal GW has a negative voltage level, and the second transistor T2 may be turned on in case that the first gate signal GW has a positive voltage level. The second terminal of the second transistor T2 may provide the data voltage VDATA to the second node N2 in case that the second transistor T2 is turned on. Accordingly, the second transistor T2 may drive the first transistor T1.

The third transistor T3 may include a gate terminal, a first terminal, and a second terminal. In an embodiment, the first terminal of the third transistor T3 may be a source, and the second terminal of the third transistor T3 may be a drain. The gate terminal of the third transistor T3 may receive the second gate signal GC through the second gate line GCL. The first terminal of the third transistor T3 may be connected to the first node N1. The second terminal of the third transistor T3 may be connected to the third node N3.

The third transistor T3 may be turned on or off in response to the second gate signal GC. For example, in case that the third transistor T3 is the n-type transistor, the third transistor T3 may be turned off in case that the second gate signal GC has a negative voltage level, and the third transistor T3 may be turned on in case that the second gate signal GC has a positive voltage level. In case that the third transistor T3 is the p-type transistor, the third transistor T3 may be turned off in case that the second gate signal GC has a positive voltage level, and the third transistor T3 may be turned on in case that the second gate signal GC has a negative voltage level. The third transistor T3 may diode-connect the first transistor T1 in case that the third transistor T3 is turned on. For example, the third transistor T3 may compensate for a threshold voltage of the first transistor T1.

The fourth transistor T4 may include a gate terminal, a first terminal, and a second terminal. In an embodiment, the first terminal of the fourth transistor T4 may be a source, and the second terminal of the fourth transistor T4 may be a drain. The gate terminal of the fourth transistor T4 may receive the third gate signal GI through the third gate line GIL. The first terminal of the fourth transistor T4 may receive the gate initialization voltage VINT through the third voltage line VL3. The second terminal of the fourth transistor T4 may be connected to the first node N1.

The fourth transistor T4 may be turned on or off in response to the third gate signal GI. For example, in case that the fourth transistor T4 is the n-type transistor, the fourth transistor T4 may be turned off in case that the third gate signal GI has a negative voltage level, and the fourth transistor T4 may be turned on in case that the third gate signal GI has a positive voltage level. In case that the fourth transistor T4 is the p-type transistor, the fourth transistor T4 may be turned off in case that the third gate signal GI has a positive voltage level, and the fourth transistor T4 may be turned on in case that the third gate signal GI has a negative voltage level. The fourth transistor T4 may provide the gate initialization voltage VINT to the first node N1 in case that the fourth transistor T4 is turned on. Accordingly, the fourth transistor T4 may initialize a voltage of the gate terminal of the first transistor T1.

The fifth transistor T5 may include a gate terminal, a first terminal, and a second terminal. In an embodiment, the first terminal of the fifth transistor T5 may be a source, and the second terminal of the fifth transistor T5 may be a drain. The gate terminal of the fifth transistor T5 may receive an emission control signal EM through the emission control line ECL. The first terminal of the fifth transistor T5 may receive the first power voltage ELVDD through the first voltage line VL1. The second terminal of the fifth transistor T5 may be connected to the second node N2.

The fifth transistor T5 may be turned on or off in response to the emission control signal EM. For example, in case that the fifth transistor T5 is the p-type transistor, the fifth transistor T5 may be turned off in case that the emission control signal EM has a positive voltage level, and the fifth transistor T5 may be turned on in case that the emission control signal EM has a negative voltage level. In case that the fifth transistor T5 is the n-type transistor, the fifth transistor T5 may be turned off in case that the emission control signal EM has a negative voltage level, and the fifth transistor T5 may be turned on in case that the emission control signal EM has a positive voltage level. The fifth transistor T5 may provide the first power voltage ELVDD to the first terminal of the first transistor T1 in case that the fifth transistor T5 is turned on.

The sixth transistor T6 may include a gate terminal, a first terminal, and a second terminal. In an embodiment, the first terminal of the sixth transistor T6 may be a source, and the second terminal of the sixth transistor T6 may be a drain. The gate terminal of the sixth transistor T6 may receive the emission control signal EM through the emission control line ECL. The first terminal of the sixth transistor T6 may be connected to the third node N3. The second terminal of the sixth transistor T6 may be connected to a fourth node N4.

The sixth transistor T6 may be turned on or off in response to the emission control signal EM. For example, in case that the sixth transistor T6 is the p-type transistor, the sixth transistor T6 may be turned off in case that the emission control signal EM has a positive voltage level, and the sixth transistor T6 may be turned on in case that the emission control signal EM has a negative voltage level. In case that the sixth transistor T6 is the n-type transistor, the sixth transistor T6 may be turned off in case that the emission control signal EM has a negative voltage level, and the sixth transistor T6 may be turned on in case that the emission control signal EM has a positive voltage level. The sixth transistor T6 may provide the driving current ID to the light emitting element LD in case that the sixth transistor T6 is turned on.

The seventh transistor T7 may include a gate terminal, a first terminal, and a second terminal. In an embodiment, the first terminal of the seventh transistor T7 may be a source, and the second terminal of the seventh transistor T7 may be a drain. The gate terminal of the seventh transistor T7 may receive the fourth gate signal GB through the fourth gate line GBL. The first terminal of the seventh transistor T7 may receive the anode initialization voltage VAINT through the fourth voltage line VL4. The second terminal of the seventh transistor T7 may be connected to the fourth node N4.

The seventh transistor T7 may be turned on or off in response to the fourth gate signal GB. For example, in case that the seventh transistor T7 is the p-type transistor, the seventh transistor T7 may be turned off in case that the fourth gate signal GB has a positive voltage level, and the seventh transistor T7 may be turned on in case that the fourth gate signal GB has a negative voltage level. In case that the seventh transistor T7 is the n-type transistor, the seventh transistor T7 may be turned off in case that the fourth gate signal GB has a negative voltage level, and the seventh transistor T7 may be turned on in case that the fourth gate signal GB has a positive voltage level. The seventh transistor T7 may provide the anode initialization voltage VAINT to the fourth node N4 in case that the seventh transistor T7 is turned on. Accordingly, the seventh transistor T7 may initialize a voltage of an anode of the light emitting element LD.

The first capacitor Cl may include a first terminal and a second terminal. The first terminal of the first capacitor C1 may receive the first power voltage ELVDD through the first voltage line VL1. The second terminal of the first capacitor Cl may be connected to the first node N1. The first capacitor CI may maintain a voltage level of the gate terminal of the first transistor T1 even in case that the second transistor T2 is turned off.

Although not illustrated in FIG. 2, the pixel driver circuit PC may further include a second capacitor. The second capacitor may include a first terminal to which the first power voltage ELVDD is provided and a second terminal connected to the first terminal of the first transistor T1.

The light emitting element LD may include the anode and a cathode. The anode of the light emitting element LD may be connected to the fourth node N4. The cathode of the light emitting element LD may receive the second power voltage ELVSS through the second voltage line VL2. The light emitting element LD may generate light having a brightness corresponding to the driving current ID.

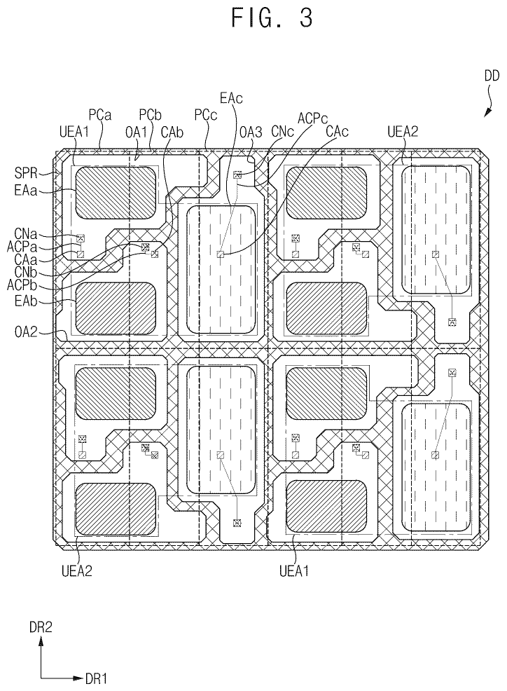

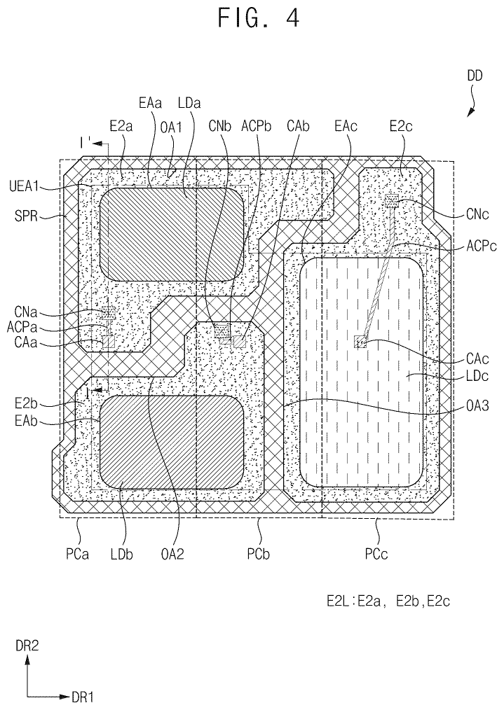

FIG. 3 is a schematic plan view illustrating a portion of the display device of FIGS. 1A and 1B according to an embodiment. FIG. 4 is an enlarged schematic view illustrating one of unit emission areas of FIG. 3 according to an embodiment. FIG. 5 is a schematic cross-sectional view taken along line I-I′ of FIG. 4 according to an embodiment.

For example, FIG. 3 illustrates a schematic view of an area in which four unit emission areas UEA1 and UEA2 forming a matrix of two rows and two columns are disposed, and FIG. 4 illustrates an enlarged schematic view of a first unit emission area UEA1 among the unit emission areas UEA1 and UEA2. For convenience of description, some of components illustrated in FIG. 5 are omitted or emphasized in FIGS. 3 and 4.

Referring to FIGS. 3 and 4, the display device DD according to an embodiment may include first to third pixel driving circuits PCa, PCb, and PCc, first to third light emitting elements LDa, LDb, and LDc, first to third auxiliary connection patterns ACPa, ACPb, and ACPc, and a separator SPR.

Each of the first to third pixel driving circuits PCa, PCb, and PCc may correspond to the pixel driving circuit PC described above with reference to FIG. 2. For example, each of the first to third pixel driving circuits PCa, PCb, and PCc may include at least one transistor and at least one capacitor. For example, each of the first to third pixel driving circuits PCa, PCb, and PCc may include a transistor TR, a first capacitor CAP1, and a second capacitor CAP2 illustrated in FIG. 5.

The transistor TR of FIG. 5 may be a transistor connected to the light emitting element through an anode connection electrode (not illustrated). For example, in case that each of the first to third pixel driving circuits PCa, PCb, and PCc is the pixel driving circuit PC of FIG. 2, the transistor TR of FIG. 5 may be the sixth transistor T6 of FIG. 2. In addition, the first capacitor CAP1 of FIG. 5 may correspond to the first capacitor C1 of FIG. 2, and the second capacitor CAP2 of FIG. 5 may be omitted. However, the disclosure is not limited thereto, the second capacitor CAP2 of FIG. 5 may correspond to the first capacitor C1 of FIG. 2, and the first capacitor CAP1 of FIG. 5 may be omitted. The transistor TR, the first capacitor CAP1, and the second capacitor CAP2 will be described in more detail later with reference to FIG. 5.

FIGS. 3 and 4 illustrate that the first to third pixel driving circuits PCa, PCb, and PCc each have a rectangular shape and are sequentially disposed in the first direction DR1 in a plan view. However, the disclosure is not limited thereto, and the shape and arrangement of the first to third pixel driving circuits PCa, PCb, and PCc may be variously changed according to embodiments of the disclosure.

Each of the first to third light emitting elements LDa, LDb, and LDc may correspond to the light emitting element LD described above with reference to FIG. 2. For example, each of the first to third light emitting elements LDa, LDb, and LDc may include a first electrode (e.g., a first electrode E1 of FIG. 5), an intermediate layer (e.g., an intermediate layer ML of FIG. 5) disposed on the first electrode, and an electrode layer E2L disposed on the intermediate layer. In an embodiment, the first electrode may function as the anode of FIG. 2, and the electrode layer E2L may function as the cathode of FIG. 2. The first electrode of the first light emitting element LDa, the first electrode of the second light emitting element LDb, and the first electrode of the second light emitting element LDc may be spaced apart from each other in a plan view. In other words, the first electrode of the first light emitting element LDa, the first electrode of the second light emitting element LDb, and the first electrode of the second light emitting element LDc may be different patterns that are physically separated from each other.

In an embodiment, the electrode layer E2L may be separated (or disconnected) into second electrodes E2a, E2b, and E2c spaced apart from each other by the separator SPR. For example, the electrode layer E2L may be separated (or disconnected) into the second electrode E2a of the first light emitting element LDa, the second electrode E2b of the second light emitting element LDb, and the second electrode E2c of the third light emitting element LDc.

The first to third light emitting elements LDa, LDb, and LDc may be connected to the first to third pixel driving circuits PCa, PCb, and PCc, respectively. Accordingly, the first pixel driving circuit PCa and the first light emitting element LDa may form a pixel, the second pixel driving circuit PCb and the second light emitting element LDb may form a pixel, and the third pixel driving circuit PCc and the third light emitting element LDc may form a pixel.

The first to third light emitting elements LDa, LDb, and LDc may emit light of different colors. For example, the first light emitting element LDa may emit red light, the second light emitting element LDb may emit green light, and the third light emitting element LDc may emit blue light. However, the disclosure is not limited thereto.

In an embodiment, as illustrated in FIG. 3, the display device DD may include the first unit emission area UEA1 and the second unit emission area UEA2. The first unit emission area UEA1 and the second unit emission area UEA2 may be defined in a matrix form in the first direction DR1 and the second direction DR2. Although FIG. 3 illustrates only four unit emission areas, multiple unit emission areas may be defined in a matrix form in the first direction DR1 and the second direction DR2 in the entire display area DA (see FIGS. 1A and 1B).

The first to third light emitting elements LDa, LDb, and LDc adjacent to each other may be disposed in each of the first unit emission area UEA1 and the second unit emission area UEA2. For example, first to third emission areas EAa, EAb, and EAc adjacent to each other may be defined in each of the first unit emission area UEA1 and the second unit emission area UEA2, and the first to third light emitting elements LDa, LDb, and LDc may be disposed in the first to third emission areas EAa, EAb, and EAc, respectively.

The first to third emission areas EAa, EAb, and EAc may be defined by pixel openings of a pixel defining layer PDL (see FIG. 5) described later. Each of the first to third emission areas EAa, EAb, and EAc may be an area where light is emitted from the light emitting element. For example, the first light emitting element LDa may be disposed in the first emission area EAa, and the first emission area EAa may be an area where light is emitted from the first light emitting element LDa. For example, the second light emitting element LDb may be disposed in the second emission area EAb, and the second emission area EAb may be an area where light is emitted from the second light emitting element LDb. For example, the third light emitting element LDc may be disposed in the third emission area EAc, and the third emission area EAc may be an area where light is emitted from the third light emitting element LDc. The first to third emission areas EAa, EAb, and EAc may emit light of different colors. For example, the first emission area EAa may emit red light, the second emission area EAb may emit green light, and the third emission area EAc may emit blue light. However, the disclosure is not limited thereto.

In an embodiment, the first unit emission area UEA1 and the second unit emission area UEA2 may be distinguished based on the arrangement of the first to third light emitting elements LDa, LDb, and LDc (or the arrangement of the first to third emission areas EAa, EAb, and EAc). For example, the arrangement of the first to third light emitting elements LDa, LDb, and LDc (or the first to third emission areas EAa, EAb, and EAc) may be the same for each first unit emission area UEA1, and the arrangement of the first to third light emitting elements LDa, LDb, and LDc (or the first to third emission areas EAa, EAb, and EAc) may be the same for each second unit emission area UEA2.

In an embodiment, as illustrated in FIG. 3, the first unit emission areas UEA1 and the second unit emission areas UEA2 may be alternately disposed in the first direction DR1 (i.e., a row direction) and the second direction DR2 (i.e., a column direction). However, the disclosure is not limited thereto, and the number of different unit emission areas included in the display device DD or the arrangement of the unit emission areas may be variously changed according to embodiments of the disclosure.

FIGS. 3 and 4 illustrate that the first to third emission areas EAa, EAb, and EAc are disposed in an S-stripe structure, but the disclosure is not limited thereto. The arrangement of the first to third emission areas EAa, EAb, and EAc may be variously changed according to embodiments of the disclosure.

In a plan view, the separator SPR may not overlap each of the first to third emission areas EAa, EAb, and EAc. In a plan view, the separator SPR may be disposed between the first to third emission areas EAa, EAb, and EAc. For example, in a plan view, the separator SPR may be disposed between the first emission area EAa and the second emission area EAb, between the second emission area EAb and the third emission area EAc, and between the first emission area EAa and the third emission area EAc. In a plan view, the separator SPR may surround at least a portion of each of the first to third emission areas EAa, EAb, and EAc. In an embodiment, as illustrated in FIGS. 3 and 4, in a plan view, the separator SPR may entirely surround each of the first to third emission areas EAa, EAb, and EAc. However, the disclosure is not limited thereto, and in a plan view, the separator SPR may surround a portion of each of the first to third emission areas EAa, EAb, and EAc and may not surround another portion of each of the first to third emission areas EAa, EAb, and EAc.

In the display area DA, the separator SPR may separate (or disconnect) the electrode layer E2L into the second electrode E2a of the first light emitting element LDa, the second electrode E2b of the second light emitting element LDb, and the second electrode E2c of the third light emitting element LDc. Accordingly, in a plan view, the second electrode E2a of the first light emitting element LDa, the second electrode E2b of the second light emitting element LDb, and the second electrode E2c of the third light emitting element LDc may be spaced apart from each other.

The separator SPR may define first to third open areas OA1, OA2, and OA3 respectively corresponding to the second electrodes E2a, E2b, and E2c. For example, in a plan view, the separator SPR may have a mesh structure surrounding the second electrodes E2a, E2b, and E2c. The second electrode E2a of the first light emitting element LDa may be disposed in the first open area OA1 of the separator SPR, the second electrode E2b of the second light emitting element LDb may be disposed in the second open area OA2 of the separator SPR, and the second electrode E2c of the third light emitting element LDc may be disposed in the third open area OA3 of the separator SPR.

In an embodiment, a planar shape of the first open area OA1 and a planar shape of the second electrode E2a of the first light emitting element LDa may be substantially the same, a planar shape of the second open area OA2 and a planar shape of the second electrode E2b of the second light emitting element LDb may be substantially the same, and a planar shape of the third open area OA3 and a planar shape of the second electrode E2c of the third light emitting element LDc may be substantially the same in a plan view.

The separator SPR may include an organic insulating material. For example, the separator SPR may include a photosensitive resin (e.g., a photoresist), but the disclosure is not limited thereto.

Hereinafter, a connection relationship between the first to third light emitting elements LDa, LDb, and LDc and the first to third auxiliary connection patterns ACPa, ACPb, and ACPc will be described in more detail, focusing on the first unit emission area UEA1 of FIG. 4. The following description of the connection relationship between the first to third light emitting elements LDa, LDb, and LDc and the first to third auxiliary connection patterns ACPa, ACPb, and ACPc may be substantially equally or similarly applied to all unit emission areas.

As described above, the display device DD may include the first to third auxiliary connection patterns ACPa, ACPb, and ACPc. The first auxiliary connection pattern ACPa may electrically connect the first light emitting element LDa and an auxiliary electrode AUE (see FIG. 5). The second auxiliary connection pattern ACPb may electrically connect the second light emitting element LDb and the auxiliary electrode. The third auxiliary connection pattern ACPc may electrically connect the third light emitting element LDc and the auxiliary electrode. The second power voltage ELVSS (see FIG. 2) may be applied to the auxiliary electrode.

The first to third auxiliary connection patterns ACPa, ACPb, and ACPc may include a conductive material, such as a metal, an alloy, a conductive metal oxide, a conductive metal nitride, a transparent conductive oxide, the like, or a combination thereof. In an embodiment, examples of the conductive material that can be used as each of the first to third auxiliary connection patterns ACPa, ACPb, and ACPc may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing Al, an alloy containing Ag, an alloy containing Cu, an alloy containing Mo, aluminum nitride (AlNₓ), tungsten nitride (WNₓ), titanium nitride (TiNₓ), chromium nitride (CrNₓ), tantalum nitride (TaNₓ), tin oxide (SnOₓ), gallium oxide (GaOₓ), indium gallium zinc oxide (IGZO), indium tin zinc oxide (ITZO), indium tin oxide (ITO), indium zinc oxide (IZO), indium gallium oxide (IGO), zinc oxide (ZnOₓ), indium oxide (InOₓ), aluminum zinc oxide (AZO), or the like. These may be used alone or in combination with each other. In an embodiment, each of the first to third auxiliary connection patterns ACPa, ACPb, and ACPc may have a single-layer structure or a multi-layer structure in which multiple conductive layers are stacked on each other. A detailed description of this will be described later with reference to FIG. 5.

The first auxiliary connection pattern ACPa may include a first auxiliary electrode connection portion CAa and a first light emitting connection portion CNa.

The first auxiliary electrode connection portion CAa may be a portion of the first auxiliary connection pattern ACPa which is connected to the auxiliary electrode AUE (see FIG. 5). For example, a position of the first auxiliary electrode connection portion CAa may correspond to a position of a contact hole that exposes the auxiliary electrode AUE and penetrates a fifth insulating layer IL5 (see FIG. 5).

The first light emitting connection portion CNa may be a portion of the first auxiliary connection pattern ACPa which is connected to the second electrode E2a of the first light emitting element LDa. For example, the first light emitting connection portion CNa may be a portion of the first auxiliary connection pattern ACPa which is exposed by a sixth insulating layer IL6 (see FIG. 5) and the pixel defining layer PDL (see FIG. 5) for being connected to the second electrode E2a. Accordingly, a position of the first light emitting connection portion CNa may correspond to a position of an opening that exposes the first auxiliary connection pattern ACPa and penetrates the pixel defining layer PDL and the sixth insulating layer IL6.

The second electrode E2a of the first light emitting element LDa may be connected to the first auxiliary connection pattern ACPa. For example, the second electrode E2a of the first light emitting element LDa may contact the first auxiliary connection pattern ACPa. As a result, the second electrode E2a of the first light emitting element LDa may be electrically connected to the auxiliary electrode AUE (see FIG. 5) through the first auxiliary connection pattern ACPa.

In an embodiment, the first light emitting connection portion CNa may be disposed at a position not overlapping the first emission area EAa. For example, the second electrode E2a of the first light emitting element LDa and the first auxiliary connection pattern ACPa may contact each other at the position not overlapping the first emission area EAa. For example, in a plan view, the first light emitting connection portion CNa may be disposed between the first emission area EAa and the separator SPR. Accordingly, the second electrode E2a of the first light emitting element LDa and the auxiliary electrode AUE may be electrically connected to each other through the first auxiliary connection pattern ACPa without reducing the size of the first emission area EAa.

The second auxiliary connection pattern ACPb may include a second auxiliary electrode connection portion CAb and a second light emitting connection portion CNb.

The second auxiliary electrode connection portion CAb may be a portion of the second auxiliary connection pattern ACPb which is connected to the auxiliary electrode. For example, a position of the second auxiliary electrode connection portion CAb may correspond to a position of a contact hole that exposes the auxiliary electrode and penetrates the fifth insulating layer.

The second light emitting connection portion CNb may be a portion of the second auxiliary connection pattern ACPb which is connected to the second electrode E2b of the second light emitting element LDb. For example, the second light emitting connection portion CNb may be a portion of the second auxiliary connection pattern ACPb which is exposed by the sixth insulating layer and the pixel defining layer for being connected to the second electrode E2b. Accordingly, a position of the second light emitting connection portion CNb may correspond to a position of an opening that exposes the second auxiliary connection pattern ACPb and penetrates the pixel defining layer and the sixth insulating layer.

In an embodiment, in a plan view, the second auxiliary connection pattern ACPb may be spaced apart from the first auxiliary connection pattern ACPa. In other words, the first auxiliary connection pattern ACPa and the second auxiliary connection pattern ACPb may be different electrodes that are distinct from each other.

The second electrode E2b of the second light emitting element LDb may be connected to the second auxiliary connection pattern ACPb. For example, the second electrode E2b of the second light emitting element LDb may contact the second auxiliary connection pattern ACPb. As a result, the second electrode E2b of the second light emitting element LDb may be electrically connected to the auxiliary electrode through the second auxiliary connection pattern ACPb.

In an embodiment, the second light emitting connection portion CNb may be disposed at a position not overlapping the second emission area EAb. For example, the second electrode E2b of the second light emitting element LDb and the second auxiliary connection pattern ACPb may contact each other at the position not overlapping the second emission area EAb. For example, in a plan view, the second light emitting connection portion CNb may be disposed between the second emission area EAb and the separator SPR. Accordingly, the second electrode E2b of the second light emitting element LDb and the auxiliary electrode may be electrically connected to each other through the second auxiliary connection pattern ACPb without reducing the size of the second emission area EAb.

The third auxiliary connection pattern ACPc may include a third auxiliary electrode connection portion CAc and a third light emitting connection portion CNc.

The third auxiliary electrode connection portion CAc may be a portion of the third auxiliary connection pattern ACPc which is connected to the auxiliary electrode. For example, a position of the third auxiliary electrode connection portion CAc may correspond to a position of a contact hole that exposes the auxiliary electrode and penetrates the fifth insulating layer.

The third light emitting connection portion CNc may be a portion of the third auxiliary connection pattern ACPc which is connected to the second electrode E2c of the third light emitting element LDc. For example, the third light emitting connection portion CNc may be a portion of the third auxiliary connection pattern ACPc which is exposed by the sixth insulating layer and the pixel defining layer for being connected to the second electrode E2c. Accordingly, a position of the third light emitting connection portion CNc may correspond to a position of an opening that exposes the third auxiliary connection pattern ACPc and penetrates the pixel defining layer and the sixth insulating layer.

In an embodiment, in a plan view, the third auxiliary connection pattern ACPc may be spaced apart from the first auxiliary connection pattern ACPa and the second auxiliary connection pattern ACPb. In other words, the first auxiliary connection pattern ACPa, the second auxiliary connection pattern ACPb, and the third auxiliary connection pattern ACPc may be different electrodes that are distinct from each other.

The second electrode E2c of the third light emitting element LDc may be connected to the third auxiliary connection pattern ACPc. For example, the second electrode E2c of the third light emitting element LDc may contact the third auxiliary connection pattern ACPc. As a result, the second electrode E2c of the third light emitting element LDc may be electrically connected to the auxiliary electrode through the third auxiliary connection pattern ACPc.

In an embodiment, the third light emitting connection portion CNc may be disposed at a position not overlapping the third emission area EAc. For example, the second electrode E2c of the third light emitting element LDc and the third auxiliary connection pattern ACPc may contact each other at the position not overlapping the third emission area EAc. For example, in a plan view, the third light emitting connection portion CNc may be disposed between the third emission area EAc and the separator SPR. Accordingly, the second electrode E2c of the third light emitting element LDc and the auxiliary electrode may be electrically connected to each other through the third auxiliary connection pattern ACPc without reducing the size of the third emission area EAc.

In an embodiment, as illustrated in FIG. 3, the shape or arrangement of each of the first to third auxiliary connection patterns ACPa, ACPb, and ACPc may be the same for each first unit emission area UEA1. The shape or arrangement of each of the first to third auxiliary connection patterns ACPa, ACPb, and ACPc may be the same for each second unit emission area UEA2.

Hereinafter, a cross-sectional structure of the display device DD will be described in more detail with reference to FIG. 5, focusing on the first emission area EAa. The following description of the cross-sectional structure of the display device DD may be substantially equally applied to all emission areas.

Further referring to FIG. 5, the display device DD may include the substrate SUB, a first bottom conductive layer BML1, a second bottom conductive layer BML2, the transistor TR, the first capacitor CAP1, the second capacitor CAP2, the auxiliary electrode AUE, the first auxiliary connection pattern ACPa, first to sixth insulating layers IL1, IL2, IL3, IL4, IL5, and IL6, the pixel defining layer PDL, the first light emitting element LDa, the separator SPR, a first dummy layer DP1, a second dummy layer DP2, and an encapsulation layer ENC.

The transistor TR may include an active pattern AP, a gate electrode GE, a first contact electrode SE, and a second contact electrode DE. The first capacitor CAP1 may include a first capacitor electrode CPE1 and a second capacitor electrode CPE2. The second capacitor CAP2 may include the first capacitor electrode CPE1 and a third capacitor electrode CPE3. The first light emitting element LDa may include the first electrode E1, the intermediate layer ML, and the second electrode E2a.

As described above, the transistor TR, the first capacitor CAP1, and the second capacitor CAP2 may be components included in the first pixel driving circuit PCa.

The substrate SUB may serve as a base of the display device DD. In an embodiment, examples of the material that can be used as the substrate SUB may include glass, quartz, silicon, polymers, or the like. These may be used alone or in combination with each other. The substrate SUB may have a single-layer structure or a multi-layer structure in which multiple layers including different materials are stacked on each other.

The first bottom conductive layer BML1, the second bottom conductive layer BML2, and the third capacitor electrode CPE3 may be disposed on the substrate SUB. In an embodiment, different electric signals may be applied to the first bottom conductive layer BML1 and the second bottom conductive layer BML2. The second power voltage ELVSS (see FIG. 2) may be applied to the second bottom conductive layer BML2. The first bottom conductive layer BML1, the second bottom conductive layer BML2, and the third capacitor electrode CPE3 may include a conductive material, such as a metal, an alloy, a conductive metal oxide, a conductive metal nitride, a transparent conductive oxide, the like, or a combination thereof.

The first insulating layer IL1 may overlap the first bottom conductive layer BML1, the second bottom conductive layer BML2, and the third capacitor electrode CPE3 and may be disposed on the substrate SUB. The first insulating layer IL1 may prevent or reduce metal atoms or impurities from diffusing from the substrate SUB to the active pattern AP. The first insulating layer IL1 may include an insulating material. In an embodiment, examples of the insulating material that can be used as the first insulating layer IL1 may include silicon oxide, silicon nitride, silicon oxynitride, or the like. These may be used alone or in combination with each other.

The active pattern AP may be disposed on the first insulating layer IL1. In an embodiment, the active pattern AP may overlap the first bottom conductive layer BML1 in a plan view. The active pattern AP may include an oxide semiconductor material, a silicon semiconductor material, and/or an organic semiconductor material. The active pattern AP may include a first contact area S, a second contact area D, and a channel area CH between the first contact area S and the second contact area D. The first contact area S and the second contact area D may have higher conductivity than the channel area CH.

In an embodiment, the active pattern AP may include an oxide semiconductor material. For example, examples of the oxide semiconductor material that can be used as the active pattern AP may include indium gallium zinc oxide (IGZO), zinc tin oxide (ZTO), indium tin zinc oxide (ITZO), the like, or a combination thereof. These may be used alone or in combination with each other. However, the disclosure is not limited thereto, and the active pattern AP may include different materials.

The second insulating layer IL2 may overlap the active pattern AP and may be disposed on the first insulating layer IL1. The second insulating layer IL2 may include an insulating material. In an embodiment, examples of the insulating material that can be used as the second insulating layer IL2 may include silicon oxide, silicon nitride, silicon oxynitride, or the like. These may be used alone or in combination with each other.

The gate electrode GE may be disposed on the second insulating layer IL2. The gate electrode GE may overlap the channel area CH of the active pattern AP in a plan view. The gate electrode GE may include a conductive material, such as a metal, an alloy, a conductive metal oxide, a conductive metal nitride, a transparent conductive oxide, the like, or a combination thereof. Although not illustrated, in an embodiment, the gate electrode GE may contact the first bottom conductive layer BML1.

The first capacitor electrode CPE1 may be disposed on the second insulating layer IL2. The first capacitor electrode CPE1 may overlap the third capacitor electrode CPE3 in a plan view. The first capacitor electrode CPE1 and the third capacitor electrode CPE3 may form the second capacitor CAP2. The first capacitor electrode CPE1 may include a conductive material, such as a metal, an alloy, a conductive metal oxide, a conductive metal nitride, a transparent conductive oxide, the like, or a combination thereof.

The third insulating layer IL3 may overlap the gate electrode GE and the first capacitor electrode CPE1 and may be disposed on the second insulating layer IL2. The third insulating layer IL3 may include an insulating material. In an embodiment, examples of the insulating material that can be used as the third insulating layer IL3 may include silicon oxide, silicon nitride, silicon oxynitride, or the like. These may be used alone or in combination with each other.

The second capacitor electrode CPE2 may be disposed on the third insulating layer IL3. The second capacitor electrode CPE2 may overlap the first capacitor electrode CPE1 in a plan view. The first capacitor electrode CPE1 and the second capacitor electrode CPE2 may form the first capacitor CAP1. The second capacitor electrode CPE2 may include a conductive material, such as a metal, an alloy, a conductive metal oxide, a conductive metal nitride, a transparent conductive oxide, the like, or a combination thereof.

The fourth insulating layer IL4 may overlap the second capacitor electrode CPE2 and may be disposed on the third insulating layer IL3. The fourth insulating layer IL4 may include an insulating material. In an embodiment, examples of the insulating material that can be used as the fourth insulating layer IL4 may include silicon oxide, silicon nitride, silicon oxynitride, or the like. These may be used alone or in combination with each other.

The first and second contact electrodes SE and DE may be disposed on the fourth insulating layer IL4. The first contact electrode SE may contact the first contact area S of the active pattern AP, and the second contact electrode DE may contact the second contact area D of the active pattern. The first and second contact electrodes SE and DE may include a conductive material, such as a metal, an alloy, a conductive metal oxide, a conductive metal nitride, a transparent conductive oxide, the like, or a combination thereof.

In an embodiment, the second contact electrode DE may contact the first bottom conductive layer BML1. However, the disclosure is not limited thereto. For example, in case that the gate electrode GE contacts the first bottom conductive layer BML1, the second contact electrode DE may not contact the first bottom conductive layer BML1.

The transistor TR including the active pattern AP, the gate electrode GE, the first contact electrode SE, and the second contact electrode DE may be formed. As described above, the transistor TR may be a transistor connected to the light emitting element through the anode connection electrode.

The auxiliary electrode AUE may be disposed in the display area DA on the substrate SUB. For example, the auxiliary electrode AUE may be disposed on the fourth insulating layer IL4 in the display area DA. The auxiliary electrode AUE may contact the second bottom conductive layer BML2. The second power voltage ELVSS (see FIG. 2) may be applied to the auxiliary electrode AUE. The auxiliary electrode AUE may include a conductive material, such as a metal, an alloy, a conductive metal oxide, a conductive metal nitride, a transparent conductive oxide, the like, or a combination thereof.

The second bottom conductive layer BML2 and the auxiliary electrode AUE may be electrically connected to each other. The second power voltage ELVSS (see FIG. 2) may be applied to the second bottom conductive layer BML2 and the auxiliary electrode AUE. The second bottom conductive layer BML2 and the auxiliary electrode AUE may be transmission lines for transmitting the second power voltage ELVSS (see FIG. 2) to the second electrodes E2a, E2b, and E2c. The second bottom conductive layer BML2 may be referred to as a first power transmission line, and the auxiliary electrode AUE may be referred to as a second power transmission line.

In an embodiment, multiple second bottom conductive layer BML2 and multiple auxiliary electrode AUE may be provided. In the entire display area DA, the second bottom conductive layers BML2 and the auxiliary electrodes AUE may define a mesh structure together in a plan view. For example, the second bottom conductive layers BML2 each extending in the second direction DR2 may be disposed in the first direction DR1, and the auxiliary electrodes AUE each extending in the first direction DR1 may be disposed in the second direction DR2. However, the disclosure is not limited thereto.

In an embodiment, at least one of the second bottom conductive layer BML2 and the auxiliary electrode AUE may extend to the peripheral area NDA (see FIGS. 1A and 1B). At least one of the second bottom conductive layer BML2 and the auxiliary electrode AUE may be connected to the second power supply line VSL2 (see FIGS. 1A and 1B) in the peripheral area, and may receive the second power voltage ELVSS (see FIG. 2) from the second power supply line. Accordingly, the second power voltage ELVSS (see FIG. 2) may be applied to the second bottom conductive layer BML2 and the auxiliary electrode AUE.

The fifth insulating layer IL5 may overlap the first contact electrode SE, the second contact electrode DE, and the auxiliary electrode AUE and may be disposed on the fourth insulating layer IL4. The fifth insulating layer IL5 may include an insulating material. For example, the fifth insulating layer IL5 may include an organic insulating material. In an embodiment, examples of the organic insulating material that can be used as the fifth insulating layer IL5 may include a photoresist, a polyacryl-based resin, a polyimide-based resin, a polyamide-based resin, a siloxane-based resin, an acrylic resin, an epoxy-based resin, or the like. These may be used alone or in combination with each other.

The first auxiliary connection pattern ACPa may be disposed on the auxiliary electrode AUE. For example, the first auxiliary connection pattern ACPa may be disposed on the fifth insulating layer IL5 in the display area DA. As described above, the first auxiliary connection pattern ACPa may be electrically connected to the auxiliary electrode AUE. For example, the first auxiliary connection pattern ACPa may contact the auxiliary electrode AUE through a contact hole CNT penetrating the fifth insulating layer IL5. Accordingly, the position of the first auxiliary electrode connection portion CAa may correspond to a position of the contact hole CNT.

The first auxiliary connection pattern ACPa may include a conductive material, such as a metal, an alloy, a conductive metal oxide, a conductive metal nitride, a transparent conductive oxide, the like, or a combination thereof. In an embodiment, the first auxiliary connection pattern ACPa may have a multi-layer structure in which multiple conductive layers are stacked on each other. For example, the first auxiliary connection pattern ACPa may include a first conductive layer CL1, a second conductive layer CL2, and a third conductive layer CL3 that are sequentially stacked on each other.

In an embodiment, the first conductive layer CL1 may include metal and/or transparent conductive oxide. In an embodiment, examples of the metal that can be used as the first conductive layer CL1 may include Ti, Mo, the like, or a combination thereof. Examples of the transparent conductive oxide that can be used as the first conductive layer CL1 may include ITO, IZO, ZnOₓ, InOₓ, IGO, AZO, the like, or a combination thereof. The first conductive layer CL1 may have a thin thickness compared to the second conductive layer CL2.

The second conductive layer CL2 may include a different material from the first conductive layer CL1. For example, the second conductive layer CL2 may include a different metal from the first conductive layer CL1. In an embodiment, examples of the metal that can be used as the second conductive layer CL2 may include Al, Cu, the like, or a combination thereof. The second conductive layer CL2 may have a thick thickness compared to the first conductive layer CL1.

The third conductive layer CL3 may include a different material from the second conductive layer CL2. For example, the third conductive layer CL3 may include a different metal and/or transparent conductive oxide than the second conductive layer CL2. In an embodiment, examples of the metal that can be used as the third conductive layer CL3 may include Ti, Mo, the like, or a combination thereof. Examples of the transparent conductive oxide that can be used as the third conductive layer CL3 may include ITO, IZO, ZnOₓ, InOₓ, IGO, AZO, the like, or a combination thereof. The third conductive layer CL3 may have a thin thickness compared to the second conductive layer CL2.

In an embodiment, the first conductive layer CL1 and the third conductive layer CL3 may include a same material. However, the disclosure is not limited thereto.

A side surface CL2-S of the second conductive layer CL2 may be recessed in a direction toward a center of the first auxiliary connection pattern ACPa from a side surface CL1-S of the first conductive layer CL1 and a side surface CL3-S of the third conductive layer CL3. In other words, the side surface CL1-S of the first conductive layer CL1 and the side surface CL3-S of the third conductive layer CL3 may protrude outward from the side surface CL2-S of the second conductive layer CL2. Accordingly, the first auxiliary connection pattern ACPa may have a tip portion due to a portion of the third conductive layer CL3 protruding compared to the second conductive layer CL2. For example, based on the same etching process, when etching the second conductive layer CL2 using an etching material having a high etch rate for the second conductive layer CL2 compared to the first conductive layer CL1 and the third conductive layer CL3, the first auxiliary connection pattern ACPa may be formed to have the tip portion.

FIG. 5 illustrates that the first auxiliary connection pattern ACPa has a three-layer structure in which the first to third conductive layers CL1, CL2, and CL3 are stacked on each other. However, the disclosure is not limited thereto, and the first auxiliary connection pattern ACPa may have a two-layer structure in which the second conductive layer CL2 and the third conductive layer CL3 are stacked on each other. For example, the first conductive layer CL1 may be omitted.

The anode connection electrode may be disposed on the fifth insulating layer IL5. Although not illustrated in the cross-sectional view of FIG. 5, the anode connection electrode may contact the second contact electrode DE and the first electrode E1. Accordingly, the anode connection electrode may electrically connect the transistor TR and the first light emitting element LDa to each other. The anode connection electrode may include a conductive material, such as a metal, an alloy, a conductive metal oxide, a conductive metal nitride, a transparent conductive oxide, the like, or a combination thereof.

The sixth insulating layer IL6 may overlap the anode connection electrode and may be disposed on the fifth insulating layer IL5. For example, the sixth insulating layer IL6 may partially overlap the first auxiliary connection pattern ACPa and may be disposed on the fifth insulating layer IL5. The sixth insulating layer IL6 may define a first sub-opening SO1 that exposes a portion of the first auxiliary connection pattern ACPa. For example, the first sub-opening SO1 may expose the tip portion of the first auxiliary connection pattern ACPa. The sixth insulating layer IL6 may include an insulating material. For example, the sixth insulating layer IL6 may include an organic insulating material. In an embodiment, examples that can be used as the sixth insulating layer IL6 may include a photoresist, a polyacryl-based resin, a polyimide-based resin, a polyamide-based resin, a siloxane-based resin, an acrylic resin, an epoxy-based resin, or the like. These may be used alone or in combination with each other.

The first electrode E1 may be disposed in the display area DA on the substrate SUB. For example, the first electrode E1 may be disposed on the sixth insulating layer IL6. The first electrode E1 may contact the anode connection electrode. Accordingly, the first electrode E1 may be electrically connected to the transistor TR through the anode connection electrode. The first electrode E1 may include a conductive material, such as a metal, an alloy, a conductive metal oxide, a conductive metal nitride, a transparent conductive oxide, the like, or a combination thereof. As described above, the first electrode E1 may function as the anode of FIG. 2.

The pixel defining layer PDL may be disposed on the substrate SUB, and may define a pixel opening exposing the first electrode E1. For example, the pixel defining layer may be disposed on the sixth insulating layer IL6 and the first electrode E1, and may define the pixel opening exposing at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially extended to each other. For example, the first sub-opening SO1 and the second sub-opening SO2 may be extended to form an opening OP, and the opening OP may expose at least a portion of the first auxiliary connection pattern ACPa. For example, the opening OP may expose the tip portion of the first auxiliary connection pattern ACPa.

The pixel defining layer PDL may include an insulating material. For example, the pixel defining layer PDL may include an organic insulating material. In an embodiment, examples of the organic insulating material that can be used as the pixel defining layer PDL may include a photoresist, a polyacryl-based resin, a polyimide-based resin, a polyamide-based resin, a siloxane-based resin, an acrylic resin, an epoxy-based resin, or the like. These may be used alone or in combination with each other. In an embodiment, the pixel defining layer PDL may further include an inorganic material or an organic material containing a light blocking material having a black color.

The separator SPR may be disposed on the pixel defining layer PDL. A width of an upper portion of the separator SPR may be greater than a width of a lower portion of the separator SPR. For example, a side surface of the separator SPR connecting an upper surface of the separator SPR and a lower surface of the separator SPR may be a reverse-tapered sloped surface. In other words, a cross-sectional shape of at least a portion of the separator SPR may be a reverse trapezoid.

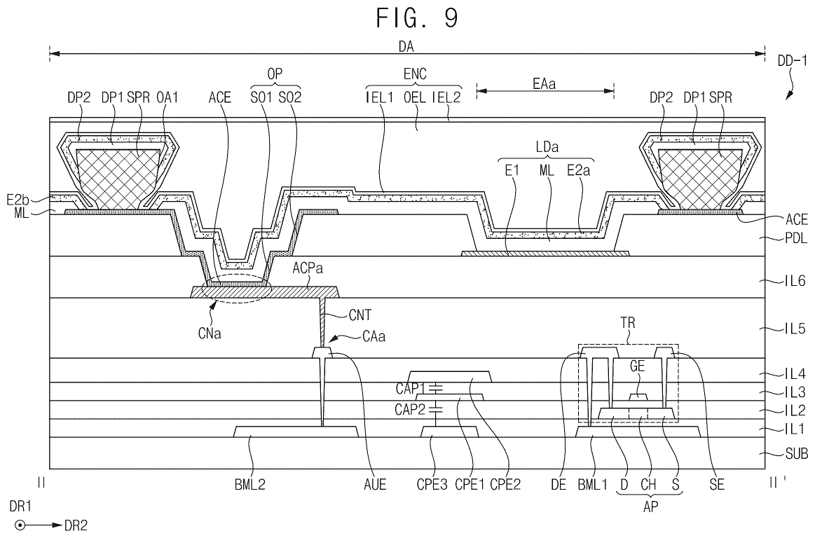

FIG. 5 illustrates that the side surface of the separator SPR has a single reverse-tapered sloped surface. However, the disclosure is not limited thereto, and the side surface of the separator SPR may have multiple reverse-tapered sloped surfaces. For example, the separator SPR may have a double reverse-tapered structure (see FIG. 9).

The intermediate layer ML may be disposed on the first electrode E1 and the pixel defining layer PDL. A portion of the intermediate layer ML may be disposed in the pixel opening of the pixel defining layer PDL. In an embodiment, the intermediate layer ML may include a first functional layer including an organic material, an emission layer disposed on the first functional layer and including an emission material, and a second functional layer disposed on the emission layer and including an organic material. For example, the first functional layer may include a hole injection layer, a hole transport layer, or the like, and the second functional layer may include an electron transport layer, an electron injection layer, the like, or a combination thereof.

A shadow area where it is difficult to deposit the intermediate layer ML may exist around the separator SPR having reverse-tapered sloped surfaces. Accordingly, in the shadow area and/or around the shadow area, the intermediate layer ML may have a structure separated (or disconnected) by the separator SPR. For example, each of the first and second functional layers included in the intermediate layer ML may have a structure separated (or disconnected) by the separator SPR. Accordingly, a leakage current (lateral leakage) between the first light emitting element LDa and other adjacent light emitting elements (e.g., the second light emitting element LDb and the third light emitting element LDc) may be prevented or reduced. For example, color mixing caused by unnecessary emission from other adjacent light emitting elements may be prevented or reduced. Accordingly, a display quality of the display device DD may be improved.

The first dummy layer DP1 may be disposed on the separator SPR. The first dummy layer DP1 may be formed by the intermediate layer ML that is separated (or disconnected) by the separator SPR. For example, the first dummy layer DP1 and the intermediate layer ML may be formed in a same process. In an embodiment, the first dummy layer DP1 may be omitted.

The intermediate layer ML may also be separated (or disconnected) by the tip portion of the first auxiliary connection pattern ACPa. Because the intermediate layer ML is separated (or disconnected) by the tip portion of the first auxiliary connection pattern ACPa, the intermediate layer ML may expose at least a portion of the side surface CL2-S of the second conductive layer CL2. Accordingly, the second electrode E2a of the first light emitting element LDa may contact the side surface CL2-S of the second conductive layer CL2.

The electrode layer E2L may be disposed on the intermediate layer ML. The electrode layer E2L may include a conductive material, such as a metal, an alloy, a conductive metal oxide, a conductive metal nitride, a transparent conductive oxide, the like, or a combination thereof. In an embodiment, the electrode layer E2L may have a single-layer structure. However, the disclosure is not limited thereto, and the electrode layer E2L may have a multi-layer structure in which multiple conductive layers are stacked on each other. For example, the electrode layer E2L may have a two-layer structure in which a first sub-electrode layer including a metal material and a second sub-electrode layer including a transparent conductive oxide are stacked on each other.

The shadow area where it is difficult to deposit the electrode layer E2L may exist around the separator SPR having reverse-tapered sloped surfaces. In the shadow area and/or around the shadow area, the electrode layer E2L may have a structure separated (or disconnected) by the separator SPR. For example, the electrode layer E2L may be separated (or disconnected) into the second electrode E2a of the first light emitting element LDa, the second electrode E2b of the second light emitting element LDb, and the second electrode E2c of the third light emitting element LDc.

The second electrode E2a of the first light emitting element LDa may be connected to the first auxiliary connection pattern ACPa. For example, the second electrode E2a may contact the side surface CL2-S of the second conductive layer CL2. For example, in case that a deposition angle of a deposition process for forming the electrode layer E2L is greater than a deposition angle of a deposition process for forming the intermediate layer ML, the electrode layer E2L (e.g., the second electrode E2a) may be formed to overlap the discontinuity in the intermediate layer ML separated (or disconnected) by the tip portion so that the electrode layer E2L may contact the side surface CL2-S of the second conductive layer CL2. As a result, the second electrode E2a may be connected to the auxiliary electrode AUE through the first auxiliary connection pattern ACPa. Accordingly, the second electrode E2a may receive the second power voltage ELVSS (see FIG. 2) from the auxiliary electrode AUE.

In an embodiment, the electrode layer E2L (e.g., the second electrode E2a) may also be separated (or disconnected) by the tip portion of the first auxiliary connection pattern ACPa. However, the disclosure is not limited thereto, the electrode layer E2L (e.g., the second electrode E2a) may be formed to extend without being separated by the tip portion.

The second dummy layer DP2 may be disposed on the separator SPR. For example, the second dummy layer DP2 may be disposed on the first dummy layer DP1. The second dummy layer DP2 may be formed by the electrode layer E2L that is separated (or disconnected) by the separator SPR. For example, the second dummy layer DP2 and the electrode layer E2L may be formed in a same process. In an embodiment, the second dummy layer DP2 may be omitted.

The encapsulation layer ENC may be disposed on the electrode layer E2L. The encapsulation layer ENC may entirely overlap the electrode layer E2L, the separator SPR, the first dummy layer DP1, and the second dummy layer DP2. In an embodiment, the encapsulation layer ENC may include a first inorganic encapsulation layer IEL1 including an inorganic insulating material, an organic encapsulation layer OEL disposed on the first inorganic encapsulation layer IEL1 and including an organic insulating material, and a second inorganic encapsulation layer IEL2 disposed on the organic encapsulation layer OEL and including an inorganic insulating material.

Although not illustrated, in an embodiment, a touch sensing layer may be disposed on the encapsulation layer ENC. For example, the touch sensing layer may include multiple touch electrode arrays for detecting a user's input in a capacitive manner, a touch pad portion, and multiple touch wires electrically connecting the touch pad portion and the touch electrode arrays. However, the disclosure is not limited thereto. In an embodiment, the touch sensing layer may be omitted.

According to embodiments of the disclosure, the display device DD may include the auxiliary electrode AUE to which the second power voltage ELVSS (see FIG. 2) is applied and the auxiliary connection patterns ACPa, ACPb, and ACPc that contact the auxiliary electrode AUE and each have the tip portion. Because the auxiliary connection patterns ACPa, ACPb, and ACPc each have the tip portion, the electrode layer E2L (e.g., the cathode) may be readily connected to the auxiliary connection patterns ACPa, ACPb, and ACPc. The electrode layer E2L may be electrically connected to the auxiliary electrode AUE through the auxiliary connection patterns ACPa, ACPb, and ACPc. Accordingly, the electrode layer E2L may receive the second power voltage from the auxiliary electrode AUE, and a voltage drop (IR drop) phenomenon of the second power voltage provided to the electrode layer E2L may be reduced. Therefore, the display quality of the display device DD may be improved.

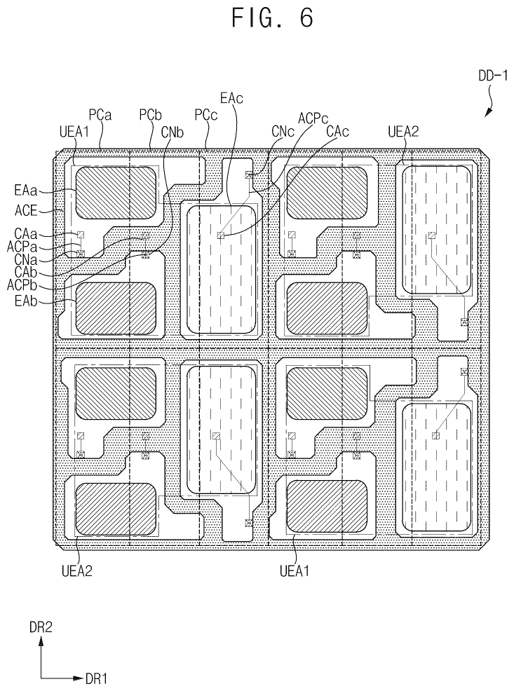

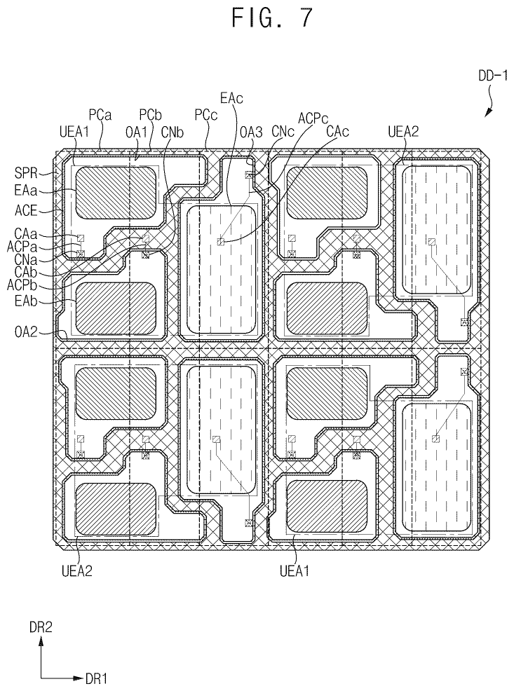

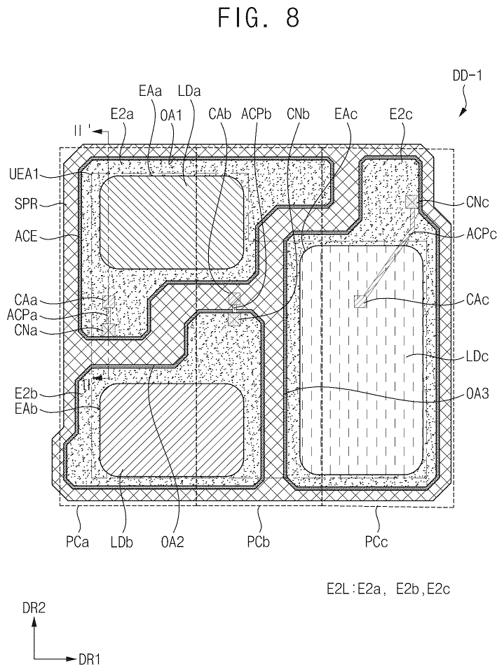

FIGS. 6 and 7 are schematic plan views illustrating a portion of a display device according to an embodiment. FIG. 8 is an enlarged schematic view illustrating one of unit emission areas of FIG. 7 according to an embodiment. FIG. 9 is a schematic cross-sectional view taken along line II-II′ of FIG. 8 according to an embodiment.

For example, FIGS. 6 and 7 illustrates schematic views of an area in which four unit emission areas UEA1 and UEA2 forming a matrix of two rows and two columns are disposed, and FIG. 8 illustrates an enlarged schematic view of a first unit emission area UEA1 among the unit emission areas UEA1 and UEA2. Each of FIGS. 6 and 7 may correspond to FIG. 3, FIG. 8 may correspond to FIG. 4, and FIG. 9 may correspond to FIG. 5.

For convenience of description, some of components illustrated in FIG. 9 are omitted or emphasized in FIGS. 6 to 8. For example, FIG. 6 is a schematic plan view illustrating first to third auxiliary connection patterns ACPa, ACPb, and ACPc and an auxiliary connection electrode ACE, and FIG. 7 is a schematic plan view illustrating a separator SPR further disposed on the auxiliary connection electrode ACE of FIG. 6.

A display device DD-1 according to an embodiment described with reference to FIGS. 6 to 9 may be substantially the same as or similar to the display device DD described above with reference to FIGS. 1A to 5, except that the display device DD-1 further includes the auxiliary connection electrode ACE electrically connecting the auxiliary connection patterns ACPa, ACPb, and ACPc and the second electrodes E2a, E2b, and E2c. Therefore, repeated description will be omitted or simplified.

Referring to FIGS. 6 to 9, the display device DD-1 according to an embodiment may include first to third pixel driving circuits PCa, PCb, and PCc, first to third light emitting elements LDa, LDb, and LDc, the first to third auxiliary connection patterns ACPa, ACPb, and ACPc, the auxiliary connection electrode ACE, and the separator SPR.

In a plan view, the auxiliary connection electrode ACE may not overlap each of the first to third emission areas EAa, EAb, and EAc. In a plan view, the auxiliary connection electrode ACE may be disposed between the first to third emission areas EAa, EAb, and EAc. For example, in a plan view, the auxiliary connection electrode ACE may be disposed between the first emission area EAa and the second emission area EAb, between the second emission area EAb and the third emission area EAc, and between the first emission area EAa and the third emission area EAc. In a plan view, the auxiliary connection electrode ACE may surround at least a portion of each of the first to third emission areas EAa, EAb, and EAc. In an embodiment, as illustrated in FIGS. 6 to 8, in a plan view, the auxiliary connection electrode ACE may entirely surround each of the first to third emission areas EAa, EAb, and EAc.

In an embodiment, the auxiliary connection electrode ACE may have a mesh structure surrounding each of the first to third emission areas EAa, EAb, and EAc in a plan view. For example, a portion of the auxiliary connection electrode ACE surrounding the first emission area EAa, a portion of the auxiliary connection electrode ACE surrounding the second emission area EAb, and a portion of the auxiliary connection electrode ACE surrounding the third emission area EAc may be integrally connected.

In a plan view, the separator SPR may be disposed between the first to third emission areas EAa, EAb, and EAc. For example, in a plan view, the separator SPR may be disposed between the first emission area EAa and the second emission area EAb, between the second emission area EAb and the third emission area EAc, and between the first emission area EAa and the third emission area EAc. In a plan view, the separator SPR may surround at least a portion of each of the first to third emission areas EAa, EAb, and EAc. In an embodiment, as illustrated in FIGS. 6 to 8, in a plan view, the separator SPR may entirely surround each of the first to third emission areas EAa, EAb, and EAc.

In the display area DA, the separator SPR may separate (or disconnect) the electrode layer E2L into the second electrode E2a of the first light emitting element LDa, the second electrode E2b of the second light emitting element LDb, and the second electrode E2c of the third light emitting element LDc. Accordingly, in a plan view, the second electrode E2a of the first light emitting element LDa, the second electrode E2b of the second light emitting element LDb, and the second electrode E2c of the third light emitting element LDc may be spaced apart from each other.

The separator SPR may define first to third open areas OA1, OA2, and OA3 respectively corresponding to the second electrodes E2a, E2b, and E2c. For example, in a plan view, the separator SPR may have a mesh structure surrounding the second electrodes E2a, E2b, and E2c. The second electrode E2a of the first light emitting element LDa may be disposed in the first open area OA1 of the separator SPR, the second electrode E2b of the second light emitting element LDb may be disposed in the second open area OA2 of the separator SPR, and the second electrode E2c of the third light emitting element LDc may be disposed in the third open area OA3 of the separator SPR. Each of the first to third open areas OA1, OA2, and OA3 may expose a portion of the auxiliary connection electrode ACE.

In an embodiment, as illustrated in FIGS. 6 to 8, in a plan view, a profile of the auxiliary connection electrode ACE may correspond to a profile of the separator SPR. In an embodiment, a width of the auxiliary connection electrode ACE may be greater than a width of the separator SPR. For example, in a plan view, the entire separator SPR may overlap the auxiliary connection electrode ACE. The separator SPR may overlap a central portion of the auxiliary connection electrode ACE in a width direction, may expose both side portions of the auxiliary connection electrode ACE in the width direction, and may not overlap the both side portions of the auxiliary connection electrode ACE. As described later, the second electrodes E2a, E2b, and E2c may contact the both side portions of the auxiliary connection electrode ACE that are exposed and not overlapped by the separator SPR.

Hereinafter, a connection relationship between the first to third light emitting elements LDa, LDb, and LDc and the first to third auxiliary connection patterns ACPa, ACPb, and ACPc will be described in more detail, focusing on the first unit emission area UEA1 of FIG. 8. The following description of the connection relationship between the first to third light emitting elements LDa, LDb, and LDc and the first to third auxiliary connection patterns ACPa, ACPb, and ACPc may be substantially equally or similarly applied to all unit emission areas.

As described above, the display device DD-1 may include the first to third auxiliary connection patterns ACPa, ACPb, and ACPc and the auxiliary connection electrode ACE. The first auxiliary connection pattern ACPa and the auxiliary connection electrode ACE may electrically connect the first light emitting element LDa and the auxiliary electrode AUE. The second auxiliary connection pattern ACPb and the auxiliary connection electrode ACE may electrically connect the second light emitting element LDb and the auxiliary electrode AUE. The third auxiliary connection pattern ACPc and the auxiliary connection electrode ACE may electrically connect the third light emitting element LDc and the auxiliary electrode AUE. The second power voltage ELVSS (see FIG. 2) may be applied to the auxiliary electrode AUE.

The first auxiliary connection pattern ACPa may include a first auxiliary electrode connection portion CAa and a first light emitting connection portion CNa.

The first auxiliary electrode connection portion CAa may be a portion of the first auxiliary connection pattern ACPa which is connected to the auxiliary electrode AUE. For example, a position of the first auxiliary electrode connection portion CAa may correspond to a position of a contact hole that exposes the auxiliary electrode and penetrates a fifth insulating layer IL5 (see FIG. 9).

The first light emitting connection portion CNa may be a portion of the first auxiliary connection pattern ACPa which is connected to the auxiliary connection electrode ACE. For example, the first light emitting connection portion CNa may be a portion of the first auxiliary connection pattern ACPa which is exposed by the sixth insulating layer IL6 and the pixel defining layer PDL to allow for connection to the auxiliary connection electrode ACE. Accordingly, a position of the first light emitting connection portion CNa may correspond to a position of an opening OP that exposes the first auxiliary connection pattern ACPa and penetrates the pixel defining layer PDL and the sixth insulating layer IL6. In a plan view, the first light emitting connection portion CNa may not overlap the first emission area EAa. For example, in a plan view, the first light emitting connection portion CNa may be disposed between the first emission area EAa and the separator SPR. For example, in a plan view, the first light emitting connection portion CNa may be disposed in the first open area OA1.

The auxiliary connection electrode ACE may be connected to the first auxiliary connection pattern ACPa. For example, the auxiliary connection electrode ACE may contact the first light emitting connection portion CNa of the first auxiliary connection pattern ACPa. However, the disclosure is not limited thereto, and the auxiliary connection electrode ACE may not contact (e.g., may not directly contact) the first auxiliary connection pattern ACPa. For example, the auxiliary connection electrode ACE may contact a capping layer that contacts the first light emitting connection portion CNa of the first auxiliary connection pattern ACPa, and may be connected to the first light emitting connection portion CNa of the first auxiliary connection pattern ACPa through the capping layer. The capping layer may include a conductive material. For example, the capping layer and the first electrode E1 may be substantially simultaneously formed and may include a same material.

The second electrode E2a of the first light emitting element LDa may be connected to the auxiliary connection electrode ACE. For example, the second electrode E2a of the first light emitting element LDa may contact the auxiliary connection electrode ACE. The second electrode E2a of the first light emitting element LDa may contact a side portion of the auxiliary connection electrode ACE that is exposed and not overlapped by the separator SPR. Accordingly, the auxiliary connection electrode ACE may electrically connect the first auxiliary connection pattern ACPa and the second electrode E2a of the first light emitting element LDa. As a result, the second electrode E2a of the first light emitting element LDa may be electrically connected to the auxiliary electrode AUE through the auxiliary connection electrode ACE and the first auxiliary connection pattern ACPa.

In an embodiment, the second electrode E2a of the first light emitting element LDa and the auxiliary connection electrode ACE may contact each other at a position not overlapping the first emission area EAa. Accordingly, the second electrode E2a of the first light emitting element LDa and the auxiliary electrode AUE may be electrically connected to each other through the auxiliary connection electrode ACE and the first auxiliary connection pattern ACPa without reducing the size of the first emission area EAa.

The second auxiliary connection pattern ACPb may include a second auxiliary electrode connection portion CAb and a second light emitting connection portion CNb. The second auxiliary electrode connection portion CAb may be a portion of the second auxiliary connection pattern ACPb which is connected to the auxiliary electrode AUE. The second light emitting connection portion CNb may be a portion of the second auxiliary connection pattern ACPb which is connected to the auxiliary connection electrode ACE. The auxiliary connection electrode ACE may electrically connect the second auxiliary connection pattern ACPb and the second electrode E2b of the second light emitting element LDb. As a result, the second electrode E2b of the second light emitting element LDb may be electrically connected to the auxiliary electrode AUE through the auxiliary connection electrode ACE and the second auxiliary connection pattern ACPb.

In a plan view, the second light emitting connection portion CNb may not overlap the second emission area EAb. For example, in a plan view, the second light emitting connection portion CNb may be disposed between the second emission area EAb and the separator SPR. For example, in a plan view, the second light emitting connection portion CNb may be disposed in the second open area OA2.

The third auxiliary connection pattern ACPc may include a third auxiliary electrode connection portion CAc and a third light emitting connection portion CNc. The third auxiliary electrode connection portion CAc may be a portion of the third auxiliary connection pattern ACPc which is connected to the auxiliary electrode AUE. The third light emitting connection portion CNc may be a portion of the third auxiliary connection pattern ACPc which is connected to the auxiliary connection electrode ACE. The auxiliary connection electrode ACE may electrically connect the third auxiliary connection pattern ACPc and the second electrode E2c of the third light emitting element LDc. As a result, the second electrode E2c of the third light emitting element LDc may be electrically connected to the auxiliary electrode AUE through the auxiliary connection electrode ACE and the third auxiliary connection pattern ACPc.

In a plan view, the third light emitting connection portion CNc may not overlap the third emission area EAc. For example, in a plan view, the third light emitting connection portion CNc may be disposed between the third emission area EAc and the separator SPR. For example, in a plan view, the third light emitting connection portion CNc may be disposed in the third open area OA3.

Hereinafter, a cross-sectional structure of the display device DD-1 will be described in more detail focusing on the first emission area EAa. The following description of the cross-sectional structure of the display device DD-1 may be substantially equally applied to all emission areas.

As illustrated in FIG. 9, the display device DD-1 may include a substrate SUB, a first bottom conductive layer BML1, a second bottom conductive layer BML2, a transistor TR, a first capacitor CAP1, a second capacitor CAP2, the auxiliary electrode AUE, an anode connection electrode, the first auxiliary connection pattern ACPa, first to sixth insulating layers IL1, IL2, IL3, IL4, IL5, and IL6, the pixel defining layer PDL, the first light emitting element LDa, the auxiliary connection electrode ACE, the separator SPR, a first dummy layer DP1, a second dummy layer DP2, and an encapsulation layer ENC. Hereinafter, description repeated with respect to the descriptions of the display device DD described above with reference to FIG. 5 will be omitted or simplified.

The second bottom conductive layer BML2 may be disposed on the substrate SUB. The second power voltage ELVSS (see FIG. 2) may be applied to the second bottom conductive layer BML2.

The auxiliary electrode AUE may be disposed on the fourth insulating layer IL4 in the display area DA. The auxiliary electrode AUE may contact the second bottom conductive layer BML2. The second power voltage may be applied to the auxiliary electrode AUE.

The second bottom conductive layer BML2 and the auxiliary electrode AUE may be electrically connected to each other. The second power voltage may be applied to the second bottom conductive layer BML2 and the auxiliary electrode AUE. The second bottom conductive layer BML2 and the auxiliary electrode AUE may be transmission lines for transmitting the second power voltage to the second electrodes E2a, E2b, and E2c. The second bottom conductive layer BML2 may be referred to as a first power transmission line, and the auxiliary electrode AUE may be referred to as a second power transmission line.

The first auxiliary connection pattern ACPa may be disposed on the fifth insulating layer IL5 in the display area DA. The first auxiliary connection pattern ACPa may be disposed between the auxiliary electrode AUE and the auxiliary connection electrode ACE. The first auxiliary connection pattern ACPa may be electrically connected to the auxiliary electrode AUE. For example, the first auxiliary connection pattern ACPa may contact the auxiliary electrode AUE through a contact hole CNT penetrating the fifth insulating layer IL5.

The sixth insulating layer IL6 may overlap the anode connection electrode and may be disposed on the fifth insulating layer IL5. In addition, for example, the sixth insulating layer IL6 may partially overlap the first auxiliary connection pattern ACPa and may be disposed on the fifth insulating layer IL5. The sixth insulating layer IL6 may define a first sub-opening SO1 that exposes at least a portion of the first auxiliary connection pattern ACPa.

The first electrode E1 may be disposed on the sixth insulating layer IL6. The first electrode E1 may contact the anode connection electrode. Accordingly, the first electrode E1 may be electrically connected to the transistor TR through the anode connection electrode.

The pixel defining layer PDL may be disposed on the sixth insulating layer IL6 and the first electrode E1. The pixel defining layer PDL may define the pixel opening exposing at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to form an opening OP. The opening OP may expose at least a portion of the first auxiliary connection pattern ACPa.

The auxiliary connection electrode ACE may be disposed on the first auxiliary connection pattern ACPa, the sixth insulating layer IL6, and the pixel defining layer PDL. As described above, the auxiliary connection electrode ACE may be connected to the first auxiliary connection pattern ACPa. For example, the auxiliary connection electrode ACE may be connected to the first auxiliary connection pattern ACPa through the opening OP penetrating the sixth insulating layer IL6 and the pixel defining layer PDL. Accordingly, the position of the first light emitting connection portion CNa may correspond to the position of the opening OP.

The auxiliary connection electrode ACE may include a conductive material, such as a metal, an alloy, a conductive metal oxide, a conductive metal nitride, a transparent conductive oxide, the like, or a combination thereof. In an embodiment, the auxiliary connection electrode ACE may have a single-layer structure or a multi-layer structure in which multiple conductive layers are stacked on each other.

In an embodiment, the auxiliary connection electrode ACE may include a transparent conductive oxide. In an embodiment, examples of the transparent conductive oxide that can be used as the auxiliary connection electrode ACE may include IGZO, ITZO, ITO, IZO, IGO, ZnOₓ, InOₓ, SnOₓ, GaOₓ, AZO, the like, or a combination thereof. These may be used alone or in combination with each other. However, the disclosure is not limited thereto, and the auxiliary connection electrode ACE may include a conductive material, such as a metal, an alloy, a conductive metal nitride, the like, or a combination thereof.

The separator SPR may be disposed on the pixel defining layer PDL and the auxiliary connection electrode ACE. In a plan view, the separator SPR may overlap the auxiliary connection electrode ACE. For example, the separator SPR may overlap a portion (e.g., a central portion in a width direction) of the auxiliary connection electrode ACE. For example, a lower surface of the separator SPR may contact an upper surface of the auxiliary connection electrode ACE.

A side surface of the separator SPR connecting an upper surface of the separator SPR and the lower surface of the separator SPR may be a reverse-tapered sloped surface. In other words, a cross-sectional shape of at least a portion of the separator SPR may be a reverse trapezoid.

In an embodiment, as illustrated in FIG. 9, the side surface of the separator SPR may have multiple reverse-tapered sloped surfaces. For example, the separator SPR may have a double reverse-tapered structure. Accordingly, the electrode layer E2L may be more readily separated (or disconnected) by the separator SPR.

The intermediate layer ML may be disposed on the first electrode E1, the pixel defining layer PDL, and the auxiliary connection electrode ACE. A portion of the intermediate layer ML may be disposed in the pixel opening of the pixel defining layer PDL.

A shadow area where it is difficult to deposit the intermediate layer ML may exist around the separator SPR having reverse-tapered sloped surfaces. Accordingly, in the shadow area and/or around the shadow area, the intermediate layer ML may have a structure separated (or disconnected) by the separator SPR. Since the intermediate layer ML has a structure separated (or disconnected), as illustrated in FIG. 9, the intermediate layer ML may expose a portion (e.g., a portion, which is adjacent to the separator SPR, of the side portion) of the auxiliary connection electrode ACE at a position adjacent to or overlapping the separator SPR. Accordingly, the second electrode E2a of the first light emitting element LDa may contact the auxiliary connection electrode ACE.

The electrode layer E2L may be disposed on the intermediate layer ML. The shadow area where it is difficult to deposit the electrode layer E2L may exist around the separator SPR having reverse-tapered sloped surfaces. In the shadow area and/or around the shadow area, the electrode layer E2L may have a structure separated (or disconnected) by the separator SPR. For example, the electrode layer E2L may be separated (or disconnected) into the second electrode E2a of the first light emitting element LDa, the second electrode E2b of the second light emitting element LDb, and the second electrode E2c of the third light emitting element LDc.

As illustrated in FIG. 9, the electrode layer E2L (e.g., the second electrode E2a) may be connected to the auxiliary connection electrode ACE. For example, the electrode layer E2L (e.g., the second electrode E2a) may contact the auxiliary connection electrode ACE at a position adjacent to or overlapping the separator SPR. For example, the electrode layer E2L (e.g., the second electrode E2a) may contact the auxiliary connection electrode ACE at an area overlapping an upper portion of the separator SPR in a plan view. For example, in case that a deposition angle of a deposition process for forming the electrode layer E2L is greater than a deposition angle of a deposition process for forming the intermediate layer ML, the electrode layer E2L (e.g., the second electrode E2a) may be formed to overlap a discontinuity in the intermediate layer ML so that the electrode layer E2L (e.g., the second electrode E2a) may contact the auxiliary connection electrode ACE. As a result, the second electrode E2a may be connected to the auxiliary electrode AUE through the auxiliary connection electrode ACE and the first auxiliary connection pattern ACPa. Accordingly, the second electrode E2a may receive the second power voltage ELVSS (see FIG. 2) from the auxiliary electrode AUE.

The encapsulation layer ENC may be disposed on the electrode layer E2L. The encapsulation layer ENC may entirely overlap the electrode layer E2L, the auxiliary connection electrode ACE, the separator SPR, the first dummy layer DP1, and the second dummy layer DP2.

According to embodiments of the disclosure, the display device DD-1 may include the auxiliary connection patterns ACPa, ACPb, and ACPc, the auxiliary connection electrode ACE, and the separator SPR. Accordingly, the electrode layer E2L (e.g., the cathode) may be readily connected to the auxiliary electrode AUE through the auxiliary connection electrode ACE and the auxiliary connection patterns ACPa, ACPb, and ACPc. Accordingly, the electrode layer E2L may receive the second power voltage from the auxiliary electrode AUE, and a voltage drop (IR drop) phenomenon of the second power voltage provided to the electrode layer E2L may be reduced. Therefore, the display quality of the display device DD-1 may be improved.

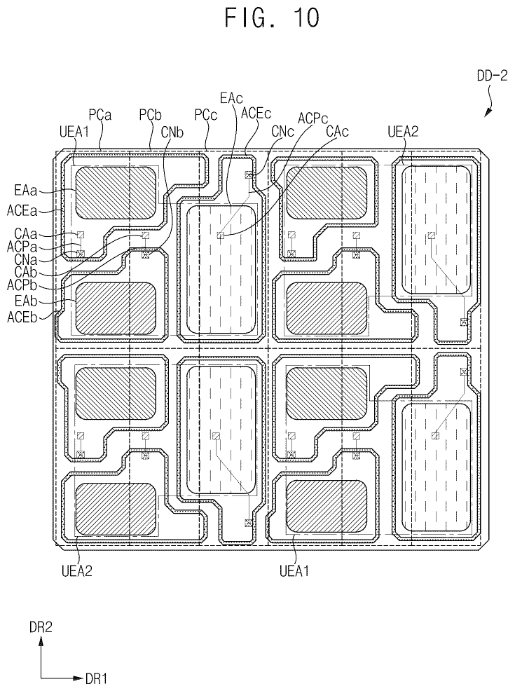

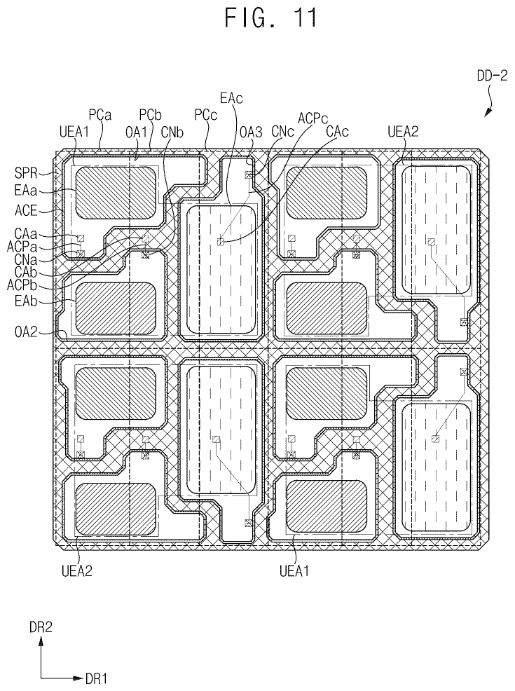

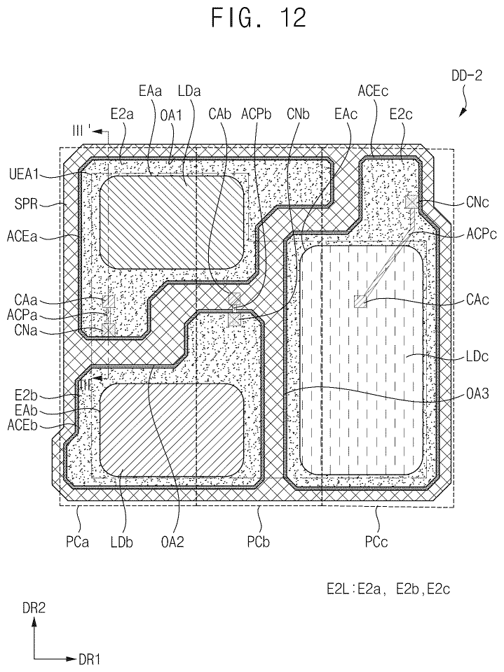

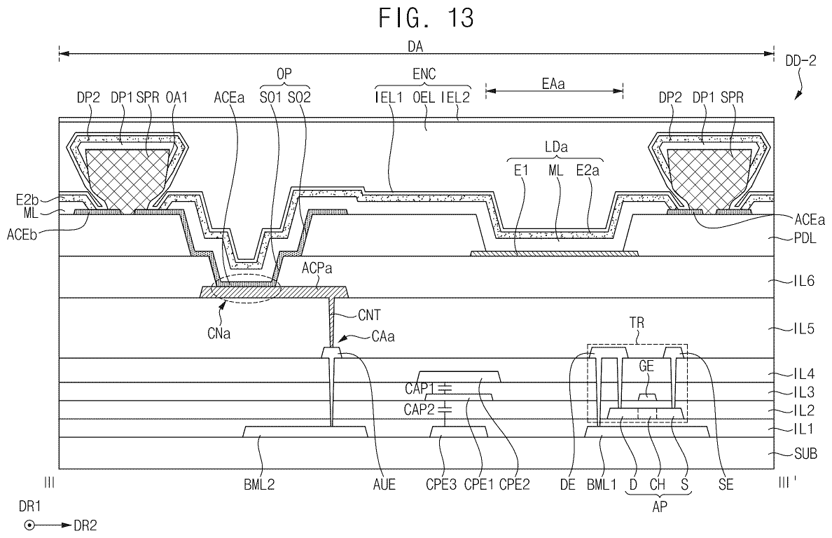

FIGS. 10 and 11 are schematic plan views illustrating a portion of a display device according to an embodiment. FIG. 12 is an enlarged schematic view illustrating one of unit emission areas of FIG. 11 according to an embodiment. FIG. 13 is a schematic cross-sectional view taken along line III-III′ of FIG. 12 according to an embodiment.

For example, FIGS. 10 and 11 illustrates schematic views of an area in which four unit emission areas UEA1 and UEA2 forming a matrix of two rows and two columns are disposed, and FIG. 12 illustrates an enlarged schematic view of a first unit emission area UEA1 among the unit emission areas UEA1 and UEA2. FIGS. 10 to 13 may correspond to FIGS. 6 to 9, respectively.

For convenience of description, some of components illustrated in FIG. 13 are omitted or emphasized in FIGS. 10 to 12. For example, FIG. 10 is a schematic plan view illustrating first to third auxiliary connection patterns ACPa, ACPb, and ACPc and first to third auxiliary connection electrodes ACEa, ACEb, and ACEc, and FIG. 11 is a schematic plan view illustrating a separator SPR further disposed on the first to third auxiliary connection patterns ACPa, ACPb, and ACPc of FIG. 10.

A display device DD-2 according to an embodiment described with reference to FIGS. 10 to 13 may be substantially the same as or similar to the display device DD-1 described above with reference to FIGS. 6 to 9, except that the auxiliary connection electrode ACE (see FIG. 6) electrically connecting the auxiliary connection patterns ACPa, ACPb, and ACPc and the second electrodes E2a, E2b, and E2c is separated into the auxiliary connection electrodes ACEa, ACEb, and ACEc spaced apart from each other. Therefore, repeated description will be omitted or simplified.

Referring to FIGS. 10 to 13, the display device DD-2 according to an embodiment may include first to third pixel driving circuits PCa, PCb, and PCc, first to third light emitting elements LDa, LDb, and LDc, the first to third auxiliary connection patterns ACPa, ACPb, and ACPc, the first to third auxiliary connection electrodes ACEa, ACEb, and ACEc, and the separator SPR.

In a plan view, the first auxiliary connection electrode ACEa may not overlap the first emission area EAa. In an embodiment, in a plan view, the first auxiliary connection electrode ACEa may surround at least a portion of the first emission area EAa. For example, as illustrated in FIG. 10, in a plan view, the first auxiliary connection electrode ACEa may have a closed ring shape entirely surround the first emission area EAa.

In a plan view, the second auxiliary connection electrode ACEb may not overlap the second emission area EAb. In an embodiment, in a plan view, the second auxiliary connection electrode ACEb may surround at least a portion of the second emission area EAb. For example, as illustrated in FIG. 10, in a plan view, the second auxiliary connection electrode ACEb may have a closed ring shape entirely surround the second emission area EAb.

In a plan view, the third auxiliary connection electrode ACEc may not overlap the third emission area EAc. In an embodiment, in a plan view, the third auxiliary connection electrode ACEc may surround at least a portion of the third emission area EAc. For example, as illustrated in FIG. 10, in a plan view, the third auxiliary connection electrode ACEc may have a closed ring shape entirely surround the third emission area EAc.

In a plan view, the first to third auxiliary connection electrodes ACEa, ACEb, and ACEc may be spaced apart from each other. In other words, the first to third auxiliary connection electrodes ACEa, ACEb, and ACEc may be different patterns that are physically separated from each other. The first to third auxiliary connection electrodes ACEa, ACEb, and ACEc may be formed in a same process. The first to third auxiliary connection electrodes ACEa, ACEb, and ACEc may be substantially simultaneously formed and may include a same material.

In a plan view, the separator SPR may be disposed between the first to third emission areas EAa, EAb, and EAc. For example, in a plan view, the separator SPR may be disposed between the first emission area EAa and the second emission area EAb, between the second emission area EAb and the third emission area EAc, and between the first emission area EAa and the third emission area EAc. In a plan view, the separator SPR may surround at least a portion of each of the first to third emission areas EAa, EAb, and EAc. In an embodiment, as illustrated in FIGS. 10 to 12, in a plan view, the separator SPR may entirely surround each of the first to third emission areas EAa, EAb, and EAc.

In the display area DA, the separator SPR may separate (or disconnect) the electrode layer E2L into the second electrode E2a of the first light emitting element LDa, the second electrode E2b of the second light emitting element LDb, and the second electrode E2c of the third light emitting element LDc. Accordingly, in a plan view, the second electrode E2a of the first light emitting element LDa, the second electrode E2b of the second light emitting element LDb, and the second electrode E2c of the third light emitting element LDc may be spaced apart from each other.

The separator SPR may define first to third open areas OA1, OA2, and OA3 respectively corresponding to the second electrodes E2a, E2b, and E2c. For example, in a plan view, the separator SPR may have a mesh structure surrounding the second electrodes E2a, E2b, and E2c. The second electrode E2a of the first light emitting element LDa may be disposed in the first open area OA1 of the separator SPR, the second electrode E2b of the second light emitting element LDb may be disposed in the second open area OA2 of the separator SPR, and the second electrode E2c of the third light emitting element LDc may be disposed in the third open area OA3 of the separator SPR. The first open area OA1 may expose a portion of the first auxiliary connection electrode ACEa, the second open area OA2 may expose a portion of the second auxiliary connection electrode ACEb, and the third open area OA3 may expose a portion of the third auxiliary connection electrode ACEc.

In a plan view, the separator SPR may partially overlap each of the first to third auxiliary connection electrodes ACEa, ACEb, and ACEc. For example, as illustrated in FIGS. 10 to 12, the first auxiliary connection electrode ACEa may include a first side portion far from the first emission area EAa in a width direction, and a second side portion close to the first emission area EAa in the width direction. The separator SPR may overlap the first side portion of the first auxiliary connection electrode ACEa, may expose the second side portion of the first auxiliary connection electrode ACEa, and may not overlap the second side portion of the first auxiliary connection electrode ACEa.

Similarly, the second auxiliary connection electrode ACEb may include a first side portion far from the second emission area EAb in a width direction, and a second side portion close to the second emission area EAb in the width direction. The separator SPR may overlap the first side portion of the second auxiliary connection electrode ACEb, may expose the second side portion of the second auxiliary connection electrode ACEb, and may not overlap the second side portion of the second auxiliary connection electrode ACEb.

The third auxiliary connection electrode ACEc may include a first side portion far from the third emission area EAc in a width direction, and a second side portion close to the third emission area EAc in the width direction. The separator SPR may overlap the first side portion of the third auxiliary connection electrode ACEc, may expose the second side portion of the third auxiliary connection electrode ACEc, and may not overlap the second side portion of the third auxiliary connection electrode ACEc.

As described later, the second electrodes E2a, E2b, and E2c may respectively contact the second side portions of the first to third auxiliary connection electrodes ACEa, ACEb, and ACEc that are exposed and not overlapped by the separator SPR.

Hereinafter, a connection relationship between the first to third light emitting elements LDa, LDb, and LDc and the first to third auxiliary connection patterns ACPa, ACPb, and ACPc will be described in more detail, focusing on the first unit emission area UEA1 of FIG. 12. The following description of the connection relationship between the first to third light emitting elements LDa, LDb, and LDc and the first to third auxiliary connection patterns ACPa, ACPb, and ACPc may be substantially equally or similarly applied to all unit emission areas.

The first auxiliary connection pattern ACPa may be disposed between the auxiliary electrode AUE and the first auxiliary connection electrode ACEa.

The first auxiliary connection electrode ACEa may be connected to the first auxiliary connection pattern ACPa. For example, the first auxiliary connection electrode ACEa may contact the first light emitting connection portion CNa of the first auxiliary connection pattern ACPa. However, the disclosure is not limited thereto, and the first auxiliary connection electrode ACEa may not contact (e.g., may not directly contact) the first auxiliary connection pattern ACPa. For example, the first auxiliary connection electrode ACEa may contact a capping layer that contacts the first light emitting connection portion CNa of the first auxiliary connection pattern ACPa, and may be connected to the first light emitting connection portion CNa of the first auxiliary connection pattern ACPa through the capping layer. The capping layer may include a conductive material. For example, the capping layer and the first electrode E1 may be substantially simultaneously formed and may include a same material.

The second electrode E2a of the first light emitting element LDa may be connected to the first auxiliary connection electrode ACEa. For example, the second electrode E2a of the first light emitting element LDa may contact the first auxiliary connection electrode ACEa. The second electrode E2a of the first light emitting element LDa may contact the second side portion of the first auxiliary connection electrode ACEa that is exposed and not overlapped by the separator SPR. Accordingly, the first auxiliary connection electrode ACEa may electrically connect the first auxiliary connection pattern ACPa and the second electrode E2a of the first light emitting element LDa. As a result, the second electrode E2a of the first light emitting element LDa may be electrically connected to the auxiliary electrode AUE through the first auxiliary connection electrode ACEa and the first auxiliary connection pattern ACPa.

In an embodiment, the second electrode E2a of the first light emitting element LDa and the first auxiliary connection electrode ACEa may contact each other at a position not overlapping the first emission area EAa. Accordingly, the second electrode E2a of the first light emitting element LDa and the auxiliary electrode AUE may be electrically connected to each other through the first auxiliary connection electrode ACEa and the first auxiliary connection pattern ACPa without reducing the size of the first emission area EAa.

The second auxiliary connection electrode ACEb may be connected to the second auxiliary connection pattern ACPb. For example, the second auxiliary connection electrode ACEb may contact the second light emitting connection portion CNb of the second auxiliary connection pattern ACPb.

The second electrode E2b of the second light emitting element LDb may be connected to the second auxiliary connection electrode ACEb. For example, the second electrode E2b of the second light emitting element LDb may contact the second auxiliary connection electrode ACEb. The second electrode E2b of the second light emitting element LDb may contact the second side portion of the second auxiliary connection electrode ACEb that is exposed and not overlapped by the separator SPR. Accordingly, the second auxiliary connection electrode ACEb may electrically connect the second auxiliary connection pattern ACPb and the second electrode E2b of the second light emitting element LDb. As a result, the second electrode E2b of the second light emitting element LDb may be electrically connected to the auxiliary electrode AUE through the second auxiliary connection electrode ACEb and the second auxiliary connection pattern ACPb.

In an embodiment, the second electrode E2b of the second light emitting element LDb and the second auxiliary connection electrode ACEb may contact each other at a position not overlapping the second emission area EAb. Accordingly, the second electrode E2b of the second light emitting element LDb and the auxiliary electrode AUE may be electrically connected to each other through the second auxiliary connection electrode ACEb and the second auxiliary connection pattern ACPb without reducing the size of the second emission area EAb.

In an embodiment, as illustrated in FIG. 13, the first auxiliary connection electrode ACEa and the second auxiliary connection electrode ACEb may be spaced from each other under the separator SPR.

The third auxiliary connection electrode ACEc may be connected to the third auxiliary connection pattern ACPc. For example, the third auxiliary connection electrode ACEc may contact the third light emitting connection portion CNc of the third auxiliary connection pattern ACPc.

The second electrode E2c of the third light emitting element LDc may be connected to the third auxiliary connection electrode ACEc. For example, the second electrode E2c of the third light emitting element LDc may contact the third auxiliary connection electrode ACEc. The second electrode E2c of the third light emitting element LDc may contact the second side portion of the third auxiliary connection electrode ACEc that is exposed and not overlapped by the separator SPR. Accordingly, the third auxiliary connection electrode ACEc may electrically connect the third auxiliary connection pattern ACPc and the second electrode E2c of the third light emitting element LDc. As a result, the second electrode E2c of the third light emitting element LDc may be electrically connected to the auxiliary electrode AUE through the third auxiliary connection electrode ACEc and the third auxiliary connection pattern ACPc.

In an embodiment, the second electrode E2c of the third light emitting element LDc and the third auxiliary connection electrode ACEc may contact each other at a position not overlapping the third emission area EAc. Accordingly, the second electrode E2c of the third light emitting element LDc and the auxiliary electrode AUE may be electrically connected to each other through the third auxiliary connection electrode ACEc and the third auxiliary connection pattern ACPc without reducing the size of the third emission area EAc.

According to embodiments of the disclosure, the display device DD-2 may include the auxiliary connection patterns ACPa, ACPb, and ACPc, the auxiliary connection electrodes ACEa, ACEb, and ACEc, and the separator SPR. Accordingly, the electrode layer E2L (e.g., the cathode) may be readily connected to the auxiliary electrode AUE through the auxiliary connection electrodes ACEa, ACEb, and ACEc and the auxiliary connection patterns ACPa, ACPb, and ACPc. Accordingly, the electrode layer E2L may receive the second power voltage from the auxiliary electrode AUE, and a voltage drop (IR drop) phenomenon of the second power voltage provided to the electrode layer E2L may be reduced. Because the auxiliary connection electrodes ACEa, ACEb, and ACEc are separated from each other, a leakage current (lateral leakage) between adjacent light emitting elements LDa, LDb, and LDc through the auxiliary connection electrodes ACEa, ACEb, and ACEc may be reduced compared to the display device DD-1 of FIGS. 6 to 9. Accordingly, a display quality of the display device DD-2 may be further improved.

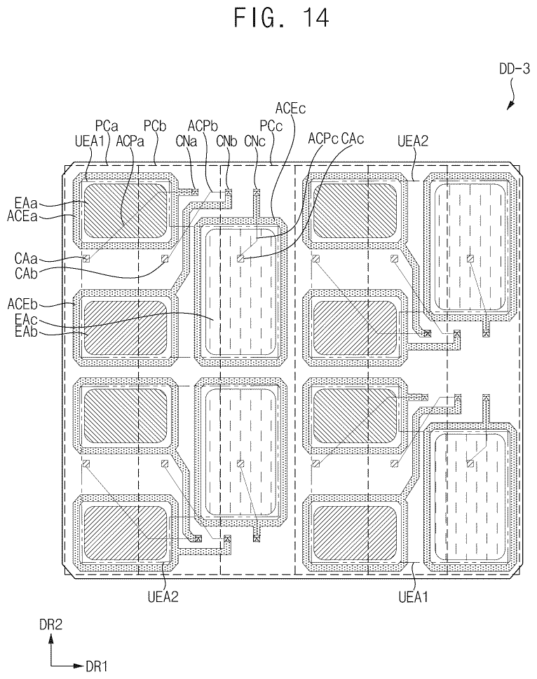

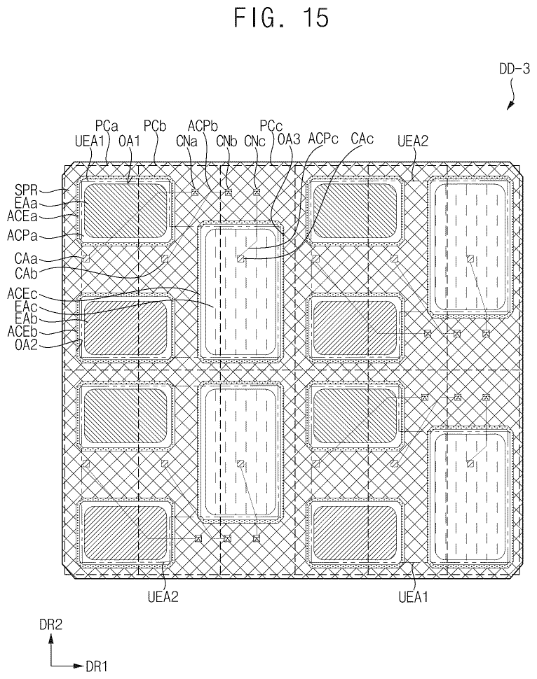

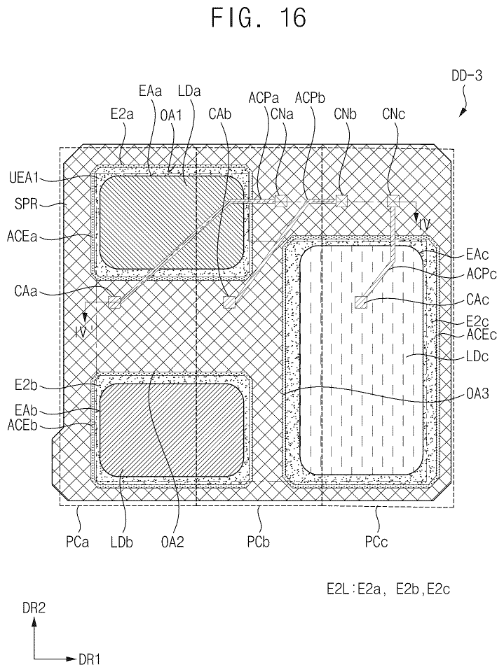

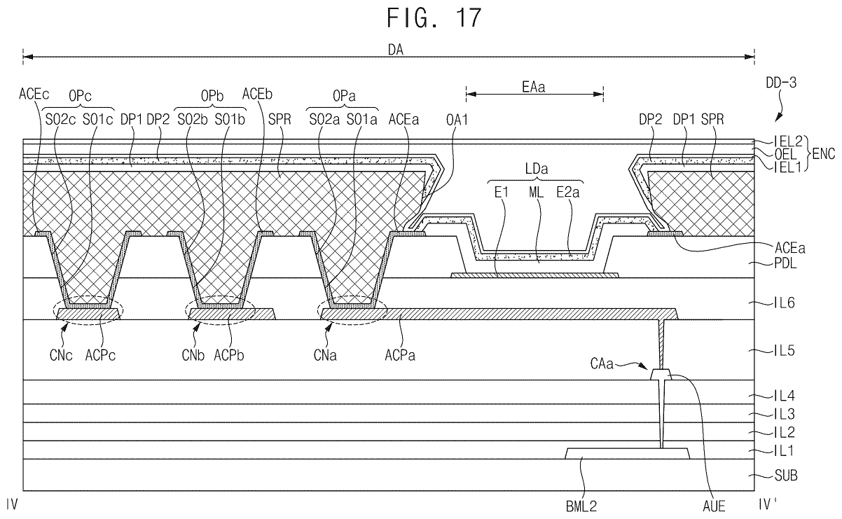

FIGS. 14 and 15 are schematic plan views illustrating a portion of a display device according to an embodiment. FIG. 16 is an enlarged schematic view illustrating one of unit emission areas of FIG. 15 according to an embodiment. FIG. 17 is a cross-sectional view taken along line IV-IV′ of FIG. 16 according to an embodiment.

For example, FIGS. 14 and 15 illustrates schematic views of an area in which four unit emission areas UEA1 and UEA2 forming a matrix of two rows and two columns are disposed, and FIG. 16 illustrates an enlarged schematic view of a first unit emission area UEA1 among the unit emission areas UEA1 and UEA2. FIGS. 14 to 17 may correspond to FIGS. 10 to 13, respectively.

For convenience of description, some of components illustrated in FIG. 17 are omitted or emphasized in FIGS. 14 to 16. For example, FIG. 14 is a schematic plan view illustrating first to third auxiliary connection patterns ACPa, ACPb, and ACPc and first to third auxiliary connection electrodes ACEa, ACEb, and ACEc, and FIG. 15 is a schematic plan view illustrating a separator SPR further disposed on the first to third auxiliary connection patterns ACPa, ACPb, and ACPc of FIG. 14.

A display device DD-3 according to an embodiment described with reference to FIGS. 14 to 17 may be substantially the same as or similar to the display device DD-2 described above with reference to FIGS. 10 to 13, except that first to third light emitting connection portions CNa, CNb, and CNc overlap the separator SPR in a plan view. Therefore, repeated description will be omitted or simplified.

Referring to FIGS. 14 to 17, the display device DD-3 according to an embodiment may include first to third pixel driving circuits PCa, PCb, and PCc, first to third light emitting elements LDa, LDb, and LDc, the first to third auxiliary connection patterns ACPa, ACPb, and ACPc, the first to third auxiliary connection electrodes ACEa, ACEb, and ACEc, and the separator SPR.

In a plan view, the first auxiliary connection electrode ACEa may not overlap the first emission area EAa. In an embodiment, in a plan view, the first auxiliary connection electrode ACEa may surround at least a portion of the first emission area EAa. For example, as illustrated in FIG. 14, in a plan view, the first auxiliary connection electrode ACEa may have a closed ring shape entirely surround the first emission area EAa.

The first auxiliary connection electrode ACEa may include a first ring portion surrounding the first emission area EAa in a plan view and a first connection portion extending from the first ring portion and connected to the first light emitting connection portion CNa of the first auxiliary connection pattern ACPa.

The first auxiliary connection electrode ACEa may be connected to the first light emitting connection portion CNa of the first auxiliary connection pattern ACPa. As illustrated in FIG. 17, the first connection portion of the first auxiliary connection electrode ACEa may contact the first light emitting connection portion CNa of the first auxiliary connection pattern ACPa through a first opening OPa to which a first-first sub-opening SO1a of the sixth insulating layer IL6 exposing the first auxiliary connection pattern ACPa and a first-second sub-opening SO2a of the pixel defining layer PDL are connected. A position of the first connection portion of the first auxiliary connection electrode ACEa and a position of the first light emitting connection portion CNa of the first auxiliary connection pattern ACPa may correspond to a position of the first opening OPa.

In an embodiment, in a plan view, each of the first connection portion of the first auxiliary connection electrode ACEa and the first light emitting connection portion CNa of the first auxiliary connection pattern ACPa may overlap the separator SPR. For example, in a plan view, the first opening OPa may overlap the separator SPR. In other words, in a plan view, the first-first sub-opening SO1a and the first-second sub-opening SO2a may overlap the separator SPR. Each of the first connection portion of the first auxiliary connection electrode ACEa and the first light emitting connection portion CNa of the first auxiliary connection pattern ACPa may be located under the separator SPR. For example, in a plan view, each of the first connection portion of the first auxiliary connection electrode ACEa and the first light emitting connection portion CNa of the first auxiliary connection pattern ACPa may be located outside the first open area OA1 of the separator SPR.

In a plan view, the second auxiliary connection electrode ACEb may not overlap the second emission area EAb. In an embodiment, in a plan view, the second auxiliary connection electrode ACEb may surround at least a portion of the second emission area EAb. For example, as illustrated in FIG. 14, in a plan view, the second auxiliary connection electrode ACEb may have a closed ring shape entirely surround the second emission area EAb.

The second auxiliary connection electrode ACEb may include a second ring portion surrounding the second emission area EAb in a plan view and a second connection portion extending from the second ring portion and connected to the second light emitting connection portion CNb of the second auxiliary connection pattern ACPb.

The second auxiliary connection electrode ACEb may be connected to the second light emitting connection portion CNb of the second auxiliary connection pattern ACPb. As illustrated in FIG. 17, the second connection portion of the second auxiliary connection electrode ACEb may contact the second light emitting connection portion CNb of the second auxiliary connection pattern ACPb through a second opening OPb to which a second-first sub-opening SO1b of the sixth insulating layer IL6 exposing the second auxiliary connection pattern ACPb and a second-second sub-opening SO2b of the pixel defining layer PDL are connected. A position of the second connection portion of the second auxiliary connection electrode ACEb and a position of the second light emitting connection portion CNb of the second auxiliary connection pattern ACPb may correspond to a position of the second opening OPb.

In an embodiment, in a plan view, each of the second connection portion of the second auxiliary connection electrode ACEb and the second light emitting connection portion CNb of the second auxiliary connection pattern ACPb may overlap the separator SPR. For example, in a plan view, the second opening OPb may overlap the separator SPR. In other words, in a plan view, the second-first sub-opening SO1b and the second-second sub-opening SO2b may overlap the separator SPR. Each of the second connection portion of the second auxiliary connection electrode ACEb and the second light emitting connection portion CNb of the second auxiliary connection pattern ACPb may be located under the separator SPR. For example, in a plan view, each of the second connection portion of the second auxiliary connection electrode ACEb and the second light emitting connection portion CNb of the second auxiliary connection pattern ACPb may be located outside the second open area OA2 of the separator SPR.

In a plan view, the third auxiliary connection electrode ACEc may not overlap the third emission area EAc. In an embodiment, in a plan view, the third auxiliary connection electrode ACEc may surround at least a portion of the third emission area EAc. For example, as illustrated in FIG. 14, in a plan view, the third auxiliary connection electrode ACEc may have a closed ring shape entirely surround the third emission area EAc.

The third auxiliary connection electrode ACEc may include a third ring portion surrounding the third emission area EAc in a plan view and a third connection portion extending from the third ring portion and connected to the third light emitting connection portion CNc of the third auxiliary connection pattern ACPc.

The third auxiliary connection electrode ACEc may be connected to the third light emitting connection portion CNc of the third auxiliary connection pattern ACPc. As illustrated in FIG. 17, the third connection portion of the third auxiliary connection electrode ACEc may contact the third light emitting connection portion CNc of the third auxiliary connection pattern ACPc through a third opening OPc to which a third-first sub-opening SO1c of the sixth insulating layer IL6 exposing the third auxiliary connection pattern ACPc and a third-second sub-opening SO2c of the pixel defining layer PDL are connected. A position of the third connection portion of the third auxiliary connection electrode ACEc and a position of the third light emitting connection portion CNc of the third auxiliary connection pattern ACPc may correspond to a position of the third opening OPc.

In an embodiment, in a plan view, each of the third connection portion of the third auxiliary connection electrode ACEc and the third light emitting connection portion CNc of the third auxiliary connection pattern ACPc may overlap the separator SPR. For example, in a plan view, the third opening OPc may overlap the separator SPR. In other words, in a plan view, the third-first sub-opening SO1c and the third-second sub-opening SO2c may overlap the separator SPR. Each of the third connection portion of the third auxiliary connection electrode ACEc and the third light emitting connection portion CNc of the third auxiliary connection pattern ACPc may be located under the separator SPR. For example, in a plan view, each of the third connection portion of the third auxiliary connection electrode ACEc and the third light emitting connection portion CNc of the third auxiliary connection pattern ACPc may be located outside the third open area OA3 of the separator SPR.

According to the display devices DD-3 of FIGS. 14 to 17, the light emitting connection portions CNa, CNb, and CNc may overlap the separator SPR in a plan view. For example, in a plan view, the light emitting connection portions CNa, CNb, and CNc may be located outside the open areas OA1, OA2, and OA3, and may not overlap the emission areas EAa, EAb, and EAc. Accordingly, the limitation of the design of each of the first to third emission areas EAa, EAb, and EAc due to the light emitting connection portions CNa, CNb, and CNc may be reduced. Therefore, the degree of design freedom of each of the first to third emission areas EAa, EAb, and EAc may be improved, and the size of each of the first to third emission areas EAa, EAb, and EAc (i.e., an aperture ratio) may be further increased.

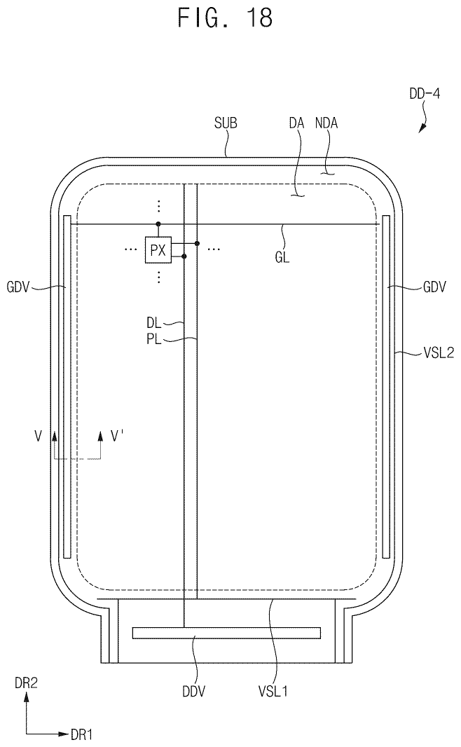

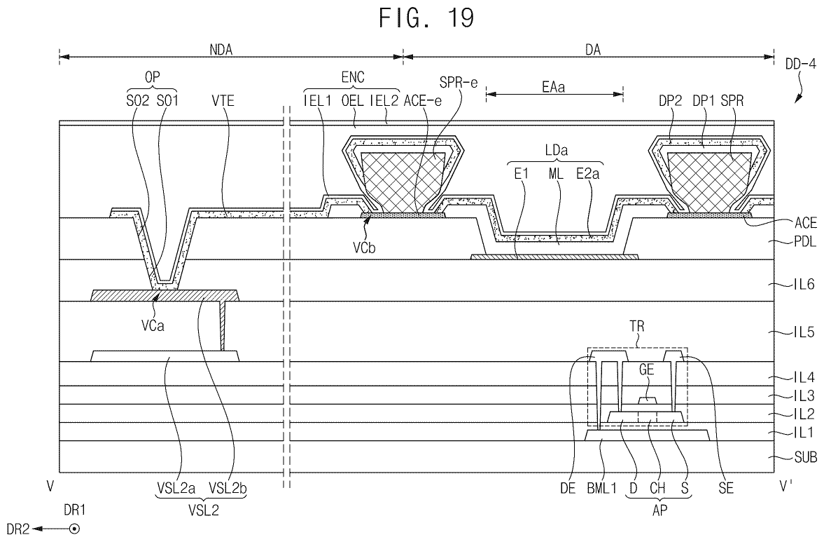

FIG. 18 is a schematic plan view illustrating a display device according to an embodiment. FIG. 19 is a schematic cross-sectional view taken along line V-V′ of FIG. 18 according to an embodiment.

A display device DD-4 according to an embodiment described with reference to FIGS. 18 and 19 may be substantially the same as or similar to the display device DD-1 described with reference to FIGS. 6 to 9, except that the auxiliary electrode AUE (see FIG. 9) and the auxiliary connection pattern ACPa (see FIG. 9) are omitted and the display device DD-4 further includes a voltage transmission electrode VTE electrically connecting a second power supply line VSL2 and an auxiliary connection electrode ACE. Therefore, repeated description will be omitted or simplified.

Referring to FIG. 18, the display device DD-4 according to an embodiment may be a device activated according to an electrical signal. For example, as illustrated in FIG. 18, the display device DD-4 may be a small-sized display device used in a small-sized electronic device, such as a smart phone, a mobile phone, a smart watch, a game console, a camera, the like, or a combination thereof. However, the disclosure is not limited thereto, and the display device DD-4 may be a medium and large-sized display device used in medium and large-sized electronic devices, such as a notebook computer, a tablet PC, a television, a computer monitor, a vehicle monitor, an external billboard, or the like.

The display device DD-4 may include a substrate SUB, pixels PX, gate lines GL, data lines DL, a data driver DDV, a gate driver GDV, power lines PL, a first power supply line VSL1, and a second power supply line VSL2. The substrate SUB, the pixels PX, the gate lines GL, the data lines DL, the data driver DDV, the gate driver GDV, the power lines PL, the first power supply line VSL1, and the second power supply line VSL2 may be substantially the same as or similar to the components described above with reference to FIGS. 1A and 1B. Therefore, repeated description will be omitted or simplified.

Referring further to FIG. 19, the display device DD-4 may include the substrate SUB, a first bottom conductive layer BML1, a transistor TR, first to sixth insulating layers IL1, IL2, IL3, IL4, IL5, and IL6, a pixel defining layer PDL, a light emitting element LD, the second power supply line VSL2, an auxiliary connection electrode ACE, the voltage transmission electrode VTE, a separator SPR, a first dummy layer DP1, a second dummy layer DP2, and an encapsulation layer ENC. Hereinafter, description repeated with respect to the descriptions of the display device DD-1 described above with reference to FIG. 9 will be omitted or simplified.

The second power supply line VSL2 may be disposed in the peripheral area NDA. The second power supply line VSL2 may receive the second power voltage ELVSS (see FIG. 2). For example, as illustrated in FIG. 18, the second power supply line VSL2 may extend along at least a portion of an edge of the display area DA.

In an embodiment, as illustrated in FIG. 19, the second power supply line VSL2 may include a first layer VSL2a and a second layer VSL2b. The first layer VSL2a and the second layer VSL2b may be in different layers. The second layer VSL2b may be disposed on the first layer VSL2a, and an insulating layer may be disposed between the first layer VSL2a and the second layer VSL2b. The second layer VSL2b may contact the first layer VSL2a through a contact hole that exposes a portion of the first layer VSL2a and penetrates the insulating layer. Accordingly, the first layer VSL2a and the second layer VSL2b may be electrically connected to each other.

In an embodiment, as illustrated in FIG. 19, the first layer VSL2a may be disposed between the fourth insulating layer IL4 and the fifth insulating layer IL5, and the second layer VSL2b may be disposed between the fifth insulating layer IL5 and the sixth insulating layer IL6.

For example, the first layer VSL2a, the first contact electrode SE, and the second contact electrode DE may be in a same layer. The first contact electrode SE, the second contact electrode DE, and the first layer VSL2a may be formed in a same process. The first contact electrode SE, the second contact electrode DE, and the first layer VSL2a may be substantially simultaneously formed and may include a same material.

For example, the second layer VSL2b and an anode connection electrode (not illustrated) electrically connecting the second contact electrode DE of the transistor TR and the first electrode E1 of the light emitting element LD may be in a same layer. The anode connection electrode and the second layer VSL2a may be formed in a same process. The anode connection electrode and the second layer VSL2a may be substantially simultaneously formed and may include a same material. However, the disclosure is not limited thereto, and the number and arrangement positions of layers included in the second power supply line VSL2 may be variously changed according to embodiments of the disclosure. For example, the first layer VSL2a may be omitted.

The auxiliary connection electrode ACE may be disposed in the display area DA. In a plan view, the auxiliary connection electrode ACE may not overlap each of the emission areas EA. In a plan view, the auxiliary connection electrode ACE may be disposed between the adjacent emission areas EA. In an embodiment, in the entire display area DA, the auxiliary connection electrode ACE may have a mesh structure surrounding each of the emission areas EA in a plan view.

The separator SPR may be disposed on the auxiliary connection electrode ACE. In a plan view, the separator SPR may not overlap each of the emission areas EA. In a plan view, the separator SPR may be disposed between the adjacent emission areas EA. In an embodiment, in the entire display area DA, the separator SPR may have a mesh structure surrounding each of the emission areas EA in a plan view.

In an embodiment, in a plan view, a profile of the auxiliary connection electrode ACE may correspond to a profile of the separator SPR. In an embodiment, a width of the auxiliary connection electrode ACE may be greater than a width of the separator SPR. For example, in a plan view, the entire separator SPR may overlap the auxiliary connection electrode ACE. The separator SPR may overlap a central portion of the auxiliary connection electrode ACE in a width direction, may expose both side portions of the auxiliary connection electrode ACE in the width direction, and may not overlap the both side portions of the auxiliary connection electrode ACE. In the display area DA, second electrodes E2a, E2b, and E2c may contact the both side portions of the auxiliary connection electrode ACE that are exposed and not overlapped by the separator SPR.

For example, the auxiliary connection electrode ACE, the separator SPR, and the second electrodes E2a, E2b, and E2c of FIG. 19 may have substantially the same planar shape as the auxiliary connection electrode ACE, the separator SPR, and the second electrodes E2a, E2b, and E2c described above with reference to FIGS. 6 to 8, respectively.

The separator SPR may separate (or disconnect) an electrode layer E2L into the second electrodes E2a, E2b, and E2c and the voltage transmission electrode VTE. For example, in the display area DA, the separator may separate (or disconnect) the electrode layer E2L into the second electrodes E2a, E2b, and E2c spaced apart from each other. In a boundary between the display area DA and the peripheral area NDA, the separator may separate (or disconnect) the electrode layer E2L into the second electrodes E2a, E2b, and E2c disposed in the display area DA and the voltage transmission electrode VTE disposed in the peripheral area NDA. In a plan view, the second electrodes E2a, E2b, and E2c and the voltage transmission electrode VTE may be spaced apart from each other.

The voltage transmission electrode VTE may be disposed in the peripheral area NDA. The voltage transmission electrode VTE may be connected to each of the auxiliary connection electrode ACE and the second power supply line VSL. The voltage transmission electrode VTE may electrically connect the auxiliary connection electrode ACE and the second power supply line VSL to each other. Accordingly, the second power voltage may be transmitted to the second electrodes E2a, E2b, and E2c of the light emitting element LD through the second power supply line VSL, the voltage transmission electrode VTE, and the auxiliary connection electrode ACE.

In an embodiment, the voltage transmission electrode VTE may be disposed on the pixel defining layer PDL. For example, the voltage transmission electrode VTE and the second electrodes E2a, E2b, and E2c of the light emitting element LD may be in a same layer. The voltage transmission electrode VTE and the second electrodes E2a, E2b, and E2c may be formed in a same process. The voltage transmission electrode VTE and the second electrodes E2a, E2b, and E2c may be substantially simultaneously formed and may include a same material. However, the disclosure is not limited thereto.

As illustrated in FIG. 18, in a plan view, a driver (e.g., the gate driver GDV and/or an emission driver) may be disposed between the second power supply line VSL2 and the display area DA. For example, circuit elements constituting the driver may be formed using various conductive layers between the substrate SUB and the pixel defining layer PDL. In case that the voltage transmission electrode VTE and the second electrodes E2a, E2b, and E2c of the light emitting element LD is in a same layer, the circuit elements of the driver may be located under the voltage transmission electrode VTE. For example, the voltage transmission electrode VTE and the circuit elements of the driver may overlap in a plan view. Accordingly, the degree of design freedom of the driver may be improved, and the peripheral area NDA of the display device DD-4 may be further reduced.

The voltage transmission electrode VTE may include a power line connection portion VCa and an auxiliary connection electrode connection portion VCb.

The power line connection portion VCa may be a portion of the voltage transmission electrode VTE which is connected to the second power supply line VSL2. For example, the power line connection portion VCa may be connected to the second layer VSL2b of the second power supply line VSL2. As illustrated in FIG. 19, the power line connection portion VCa may contact the second layer VSL2b through an opening OP to which a first sub-opening SO1 of the sixth insulating layer IL6 exposing the second layer VSL2b and a second sub-opening SO2 of the pixel defining layer PDL are connected.

The auxiliary connection electrode connection portion VCb may be a portion of the voltage transmission electrode VTE which is connected to the auxiliary connection electrode ACE. For example, the auxiliary connection electrode connection portion VCb may be connected to an edge portion ACE-e of the auxiliary connection electrode ACE located at the boundary between the display area DA and the peripheral area NDA.

As illustrated in FIG. 19, the edge portion ACE-e of the auxiliary connection electrode ACE may be located at the boundary between the display area DA and the peripheral area NDA. The edge portion ACE-e of the auxiliary connection electrode ACE may be a portion (e.g., an outermost edge portion in a plan view) of the auxiliary connection electrode ACE having a mesh structure in the entire display area DA which is closest to the peripheral area NDA. For example, a portion of the edge portion ACE-e of the auxiliary connection electrode ACE may be located in the display area DA, and another portion of the edge portion ACE-e of the auxiliary connection electrode ACE may be located in the peripheral area NDA.

An edge portion SPR-e (or an outer portion) of the separator SPR may be located at the boundary between the display area DA and the peripheral area NDA. The edge portion SPR-e of the separator SPR may be a portion (e.g., an outermost edge portion in a plan view of the separator SPR having a mesh structure in the entire display area DA which is closest to the peripheral area NDA. For example, a portion of the edge portion SPR-e of the separator SPR may be located in the display area DA, and another portion of the edge portion SPR-e of the separator SPR may be located in the peripheral area NDA.

In a plan view, the edge portion SPR-e of the separator SPR may overlap the edge portion ACE-e of the auxiliary connection electrode ACE. The edge portion SPR-e of the separator SPR may be disposed on the edge portion ACE-e of the auxiliary connection electrode ACE. A width of the edge portion ACE-e of the auxiliary connection electrode ACE may be greater than a width of the edge portion SPR-e of the separator SPR.

The edge portion ACE-e of the auxiliary connection electrode ACE may include a first side portion (e.g., a right side portion in FIG. 19) located in the display area DA in a width direction (e.g., the second direction DR2 in FIG. 19), a second side portion (e.g., a left side portion in FIG. 19) located in the peripheral area NDA in the width direction, and a central portion between the first side portion and the second side portion.

The edge portion SPR-e of the separator SPR may overlap the central portion of the edge portion ACE-e of the auxiliary connection electrode ACE, may expose the first side portion and the second side portion of the edge portion ACE-e of the auxiliary connection electrode ACE, and may not overlap the first side portion and the second side portion of the edge portion ACE-e of the auxiliary connection electrode ACE.

The second electrodes E2a, E2b, and E2c of the light emitting element LD may contact the first side portion of the edge portion ACE-e of the auxiliary connection electrode ACE that is exposed and not overlapped by the edge portion SPR-e of the separator SPR. The auxiliary connection electrode connection portion VCb of the voltage transmission electrode VTE may contact the second side portion of the edge portion ACE-e of the auxiliary connection electrode ACE that is exposed and not overlapped by the edge portion SPR-e of the separator SPR.

In an embodiment, as illustrated in FIG. 19, a side surface of the edge portion SPR-e of the separator SPR may have multiple reverse-tapered sloped surfaces. For example, the edge portion SPR-e of the separator SPR may have a double reverse-tapered structure.

A shadow area where it is difficult to deposit the electrode layer E2L may exist around the edge portion SPR-e of the separator SPR having reverse-tapered sloped surfaces. Accordingly, in the shadow area and/or around the shadow area, the electrode layer E2L may have a structure separated (or disconnected) by the edge portion SPR-e of the separator SPR. For example, the electrode layer E2L may be separated (or disconnected) into the second electrodes E2a, E2b, and E2c of the light emitting element LD disposed in the display area DA and the voltage transmission electrode VTE disposed in the peripheral area NDA by the edge portion SPR-e of the separator SPR.

In the display area DA, the second electrodes E2a, E2b, and E2c may contact the first side portion of the edge portion ACE-e of the auxiliary connection electrode ACE at a position adjacent to or overlapping the edge portion SPR-e of the separator SPR. For example, in the display area DA, the second electrodes E2a, E2b, and E2c may contact the first side portion of the edge portion ACE-e of the auxiliary connection electrode ACE at an area overlapping an upper portion of the edge portion SPR-e of the separator SPR in a plan view.

In the peripheral area NDA, the auxiliary connection electrode connection portion VCb may contact the second side portion of the edge portion ACE-e of the auxiliary connection electrode ACE at a position adjacent to or overlapping the edge portion SPR-e of the separator SPR. For example, in the peripheral area NDA, the auxiliary connection electrode connection portion VCb may contact the second side portion of the edge portion ACE-e of the auxiliary connection electrode ACE at an area overlapping an upper portion of the edge portion SPR-e of the separator SPR in a plan view.

For example, in case that a deposition angle of a deposition process for forming the electrode layer E2L is greater than a deposition angle of a deposition process for forming the intermediate layer ML, the electrode layer E2L (e.g., the second electrode E2a) may be formed to overlap the intermediate layer ML separated (or disconnected) and to contact the auxiliary connection electrode ACE. For example, the electrode layer E2L may be formed to overlap the intermediate layer ML separated (or disconnected) and to contact the first side portion of the edge portion ACE-e of the auxiliary connection electrode ACE, and the voltage transmission electrode VTE may be formed to overlap the intermediate layer ML separated (or disconnected) and to contact the second side portion of the edge portion ACE-e of the auxiliary connection electrode ACE. As a result, the second electrodes E2a, E2b, and E2c may be connected to the second power supply line VSL2 through the edge portion ACE-e of the auxiliary connection electrode ACE and the voltage transmission electrode VTE. Accordingly, the second electrodes E2a, E2b, and E2c may receive the second power voltage ELVSS (see FIG. 2). The auxiliary connection electrode ACE may have a mesh structure in the entire display area DA, and the second electrodes E2a, E2b, and E2c of all the light emitting elements LD in the display area DA may contact the auxiliary connection electrode ACE. Accordingly, all the second electrodes E2a, E2b, and E2c in the display area DA may receive the second power voltage through the auxiliary connection electrode ACE.

According to the display devices DD-4 of FIGS. 18 and 19, the second electrodes E2a, E2b, and E2c of the light emitting element LD may be readily electrically connected to the second power supply line VSL2 disposed in the peripheral area NDA through the auxiliary connection electrode ACE and the voltage transmission electrode VTE. For example, other electrodes and/or lines (e.g., the auxiliary electrode AUE and the second bottom conductive layer BML2 of FIG. 9) for transmitting the second power voltage to the second electrodes E2a, E2b, and E2c (e.g., the cathode) may not be disposed in the display area DA. As a result, the degree of design freedom of the display area DA and each of the first to third emission areas EAa, EAb, and EAc included in the display area DA may be improved, and the size of each of the first to third emission areas EAa, EAb, and EAc (i.e., an aperture ratio) may be further increased.

FIG. 20 is a schematic block diagram illustrating an electronic device according to an embodiment.

Referring to FIG. 20, in an embodiment, an electronic device 900 may include a processor 910, a memory device 920, a storage device 930, an input/output (“I/O”) device 940, a power supply 950, and a display device 960. Here, the display device 960 may correspond to one of the display devices DD, DD-1, DD-2, DD-3, and DD-4 described above. The electronic device 900 may further include multiple ports for communicating with a video card, a sound card, a memory card, a universal serial bus (“USB”) device, or the like.

The processor 910 may perform various computing functions or tasks. In an embodiment, the processor 910 may be a microprocessor, a central processing unit (“CPU”), an application processor (“AP”), or the like. The processor 910 may be electrically connected to other components via an address bus, a control bus, a data bus, or the like. In an embodiment, the processor 910 may be electrically connected to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The display device 960 may be electrically connected to other components via the buses or other communication links. In an embodiment, the display device 960 may be included in the I/O device 940.

FIG. 21 is a schematic view illustrating an example in which the electronic device of FIG. 20 is implemented as a smartphone. FIG. 22 is an exploded schematic plan view of the electronic device of FIG. 21.

Referring to FIG. 21, in an embodiment, the electronic device 900 may be implemented as a smartphone. However, the electronic device 900 may not be limited thereto, and for example, the electronic device 900 may be implemented as a television, a mobile phone, a video phone, a smart pad, a smart watch, a tablet PC, a vehicle navigation, a computer monitor, a notebook computer, a head mounted display (“HMD”), a kiosk, or the like. Hereinafter, an embodiment in which the electronic device 900 is implemented as a smartphone will be described in more detail with reference to FIGS. 21 and 22.

Referring to FIGS. 21 and 22, in an embodiment, the electronic device 900 may include a window WU, a display device 960, and a housing HM. The window WU and the housing HM may be combined to define the external appearance of the electronic device 900.

The display device 960 may display an image. The display device 960 may include the display area DA displaying the image and the peripheral area NDA located around the display area DA. The pixels PX for generating the image may be disposed in the display area DA. A driver (e.g., a data driver DDV) for driving the pixels PX may be disposed in the peripheral area NDA. The display device 960 may correspond to one of the display devices DD, DD-1, DD-2, DD-3, and DD-4 described above.

The window WU may define a front surface (or an upper surface) of the electronic device 900. The window WU may have light-transmitting properties. For example, the window WU may include a resin film such as polyimide or ultra-thin glass.

The housing HM may be combined with the window WU. The housing HM may be combined with the window WU to provide an internal space. The display device 960 may be accommodated in the internal space provided between the housing HM and the window WU. Various components, such as an optical film, a cushion layer, a heating layer, the processor, the memory device, the storage device, the I/O device, the power supply, or the like may be further accommodated in the internal space. The housing HM can include a material having high rigidity. The housing HM can stably protect the components accommodated in the internal space from external impact.

Although embodiments of the disclosure and implementations have been described herein, other embodiments and modifications will be apparent from this description. Accordingly, the invention is not limited to such embodiments, but rather to the broader scope of the appended claims and various obvious modifications and equivalent arrangements as would be apparent to a person of ordinary skill in the art.

What is claimed is:

1. A display device comprising:
a substrate including a display area and a peripheral area disposed around the display area;
a power supply line disposed in the peripheral area and supplying a low power voltage;
a plurality of first electrodes disposed in the display area and supplied with a high power voltage;
a pixel defining layer disposed on the first electrodes and exposing a portion of each of the plurality of first electrodes to define an emission area;
an auxiliary connection electrode disposed on the pixel defining layer and electrically connected to the power supply line;
an electrode layer disposed on the plurality of first electrodes and the auxiliary connection electrode, electrically connected to the auxiliary connection electrode, and supplied with the low power voltage; and
a separator disposed on the auxiliary connection electrode, overlapping a portion of the auxiliary connection electrode, and separating the electrode layer into a plurality of second electrodes spaced apart from each other in the display area.

2. The display device of claim 1, further comprising:
an auxiliary electrode disposed in the display area and electrically connected to the power supply line; and
an auxiliary connection pattern disposed between the auxiliary electrode and the auxiliary connection electrode, the auxiliary connection pattern including an auxiliary electrode connection portion connected to the auxiliary electrode and a light emitting connection portion connected to the auxiliary connection electrode.

3. The display device of claim 2, wherein in a plan view, the light emitting connection portion is disposed between the emission area and the separator.

4. The display device of claim 2, wherein in a plan view, the light emitting connection portion overlaps the separator.

5. The display device of claim 1, wherein
the pixel defining layer defines first, second, and third emission areas emitting light of different colors, and
the plurality of second electrodes spaced apart from each other by the separator respectively overlap the first, second, and third emission areas.

6. The display device of claim 5, wherein in a plan view, the separator has a mesh structure surrounding each of the plurality of second electrodes.

7. The display device of claim 5, wherein in a plan view, the auxiliary connection electrode has a mesh structure surrounding each of the first, second, and third emission areas.

8. The display device of claim 7, wherein in a plan view, a profile of the auxiliary connection electrode corresponds to a profile of the separator.

9. The display device of claim 8, wherein a width of the auxiliary connection electrode is greater than a width of the separator in a plan view.

10. The display device of claim 9, wherein
the separator overlaps a central portion in a width direction of the auxiliary connection electrode and exposes opposing side portions in the width direction of the auxiliary connection electrode, and
in the display area, the plurality of second electrodes contact the opposing side portions of the auxiliary connection electrode exposed by the separator.

11. The display device of claim 7, further comprising:
a voltage transmission electrode disposed on the power supply line, the voltage transmission electrode including a power line connection portion connected to the power supply line and an auxiliary connection electrode connection portion connected to the auxiliary connection electrode.

12. The display device of claim 11, wherein
the voltage transmission electrode and the plurality of second electrodes are disposed in a same layer, and
in a boundary between the display area and the peripheral area, the separator separates the electrode layer into the plurality of second electrodes disposed in the display area and the voltage transmission electrode disposed in the peripheral area.

13. The display device of claim 11, wherein
an edge portion of the separator is disposed at a boundary between the display area and the peripheral area,
an edge portion of the auxiliary connection electrode is disposed at the boundary between the display area and the peripheral area, and includes a first side portion disposed in the display area in a width direction, a second side portion disposed in the peripheral area in the width direction, and a central portion disposed between the first side portion and the second side portion,
the edge portion of the separator overlaps the central portion of the auxiliary connection electrode,
the separator exposes each of the first side portion and the second side portion of the auxiliary connection electrode, and
in the peripheral area, the auxiliary connection electrode connection portion of the voltage transmission electrode contacts the second side portion of the auxiliary connection electrode exposed by the edge portion of the separator.

14. The display device of claim 13, wherein in the display area, the plurality of second electrodes contact the first side portion of the auxiliary connection electrode exposed by the edge portion of the separator.

15. The display device of claim 5, wherein the auxiliary connection electrode includes first, second, and third auxiliary connection electrodes respectively surrounding the first, second, and third emission areas in a plan view.

16. The display device of claim 15, wherein in a plan view, the first, second, and third auxiliary connection electrodes are spaced apart from each other.

17. The display device of claim 15, wherein in a plan view, each of the first, second, and third auxiliary connection electrodes has a closed ring shape.

18. The display device of claim 15, wherein
the first auxiliary connection electrode includes a first side portion that is far from the first emission area in a width direction and a second side portion that is close to the first emission area in the width direction,
the separator overlaps the first side portion of the first auxiliary connection electrode and exposes the second side portion of the first auxiliary connection electrode, and
in the display area, one of the plurality of second electrodes overlapping the first emission area contacts the second side portion of the first auxiliary connection electrode exposed by the separator.

19. A display device comprising:
a substrate including a display area and a peripheral area disposed around the display area;
a power supply line disposed in the peripheral area and supplying a low power voltage;
an auxiliary electrode disposed in the display area and electrically connected to the power supply line;
an auxiliary connection pattern disposed on the auxiliary electrode, electrically connected to the auxiliary electrode, and including a first conductive layer and a second conductive layer sequentially stacked on each other, the auxiliary connection pattern having a tip portion defined by a portion of the second conductive layer protruding from the first conductive layer;
a plurality of first electrodes disposed in the display area and supplied with a high power voltage;
a pixel defining layer disposed on the auxiliary connection pattern and the plurality of first electrodes and exposing a portion of each of the plurality of first electrodes to define an emission area;
an electrode layer disposed on the auxiliary connection pattern and the plurality of first electrodes, electrically connected to the auxiliary connection pattern, and supplied with the low power voltage; and
a separator disposed on the pixel defining layer and separating the electrode layer into a plurality of second electrodes spaced apart from each other in the display area.

20. An electronic device comprising:
a window;
a housing coupled with the window to provide an internal space; and
a display device accommodated in the internal space provided between the housing and the window, the display device including:
a substrate including a display area and a peripheral area disposed around the display area;
a power supply line disposed in the peripheral area and supplying a low power voltage;
a plurality of first electrodes disposed in the display area and supplied with a high power voltage;
a pixel defining layer disposed on the plurality of first electrodes and exposing a portion of each of the plurality of first electrodes to define an emission area;
an auxiliary connection electrode disposed on the pixel defining layer and electrically connected to the power supply line;
an electrode layer disposed on the plurality of first electrodes and the auxiliary connection electrode, electrically connected to the auxiliary connection electrode, and supplied with the low power voltage; and
a separator disposed on the auxiliary connection electrode, overlapping a portion of the auxiliary connection electrode, and separating the electrode layer into a plurality of second electrodes spaced apart from each other in the display area.
